(19) United States
(12) Patent Application Publication
(10) Pub. No.: US 2026/0262192 A1
(43) Pub. Date: Sep. 3, 2026

(54) CUSTOMIZABLE AND MODULAR COOLING MANIFOLD FOR DATACENTER

(71) Applicant: MELLANOX TECHNOLOGIES, LTD., Yokneam (IL)

(72) Inventors: Shalom Alexander Gurevich, Karmiel (IL); Yuval Blayer, Avtalyon (IL); Igal Gutman, Hod HaSharon (IL); Dikla Lidya Ben Joseph, Ra'anana (IL)

(21) Appl. No.: 19/069,131

(22) Filed: Mar. 3, 2025

(51) Int. Cl. H05K 7/20

(52) U.S. Cl. CPC H05K 7/20272; H05K 7/2079

(57) ABSTRACT

Systems and methods disclosed herein are for cooling using segment cooling loops which may include manifold modules. The manifold modules may include individual outlets to direct a cooling fluid and may include lids at different ends of the manifold modules. The lids may reduce a flow velocity of the cooling fluid, by a predetermined threshold, at the individual outlets of the manifold modules.

### TECHNICAL FIELD

This disclosure is directed to liquid cooling systems in general and specifically to manifolds for use within a liquid cooling system.

### BACKGROUND

Datacenter cooling systems may use water or other cooling fluids to remove heat from computing devices. Manifold systems may be arranged for different racks or other storage configurations in order to direct a cooling fluid toward the computing devices. The manifold system may also allow removal of heated cooling fluid from the cooling devices. The manifold systems may have configurations that are limited in terms of customizability and/or accessibility. For example, as computing density increases in racks, computing devices may be arranged in stacked configurations with limited space. The limited spaces may have limited accessibility which may affect repair or maintenance activities.

### BRIEF DESCRIPTION OF THE DRAWINGS

Various embodiments in accordance with the present disclosure will be described with reference to the drawings, in which:

FIG. 1A illustrates an environment for a liquid cooling system that is subject to a customizable and modular manifold in a datacenter, in accordance with at least one embodiment.

FIG. 1B illustrates an example datacenter having a liquid cooling system of FIG. 1A that may be used with one or more racks, in accordance with at least one embodiment;

FIG. 1C illustrates control aspects of a secondary cooling loop of FIG. 1A that may be used with one or more racks, in accordance with at least one embodiment;

FIG. 1D illustrates further aspects of a liquid cooling system of FIG. 1A that may be used with one or more racks, in accordance with at least one embodiment;

FIG. 1E is an illustration of server aspects of a liquid cooling system, in at least one embodiment;

FIG. 2A illustrates a system of stacked printed circuit boards (PCBs) with at least one customizable and modular, in accordance with at least one embodiment;

FIG. 2B is a view of a single PCB with a single cold plate and may be from the system in FIG. 2A, in accordance with at least one embodiment;

FIG. 2C is a view of a cold plate, in accordance with at least one embodiment;

FIG. 2D illustrates an exploded view of a stacked set of cold plates, in accordance with at least one embodiment;

FIG. 3A illustrates an exploded view of an embodiment of a manifold having manifold modules, in accordance with at least one embodiment;

FIG. 3B illustrates an exploded view of an embodiment of a manifold module with a lid, in accordance with at least one embodiment;

FIG. 3C illustrates an exploded side view of a manifold, in accordance with at least one embodiment;

FIG. 3D illustrates a cross-sectional side view of a passage formed from the manifold modules, in accordance with at least one embodiment;

FIG. 3E illustrates a detailed cross-sectional view taken along the area labeled 3E in FIG. 3D, in accordance with at least one embodiment;

FIG. 3F illustrates a detailed cross-sectional view taken along the area labeled 3F in FIG. 3D, in accordance with at least one embodiment;

FIG. 3G illustrates a side view of a manifold in which the manifold modules are shown as transparent to illustrate the seals and the fasteners, in accordance with at least one embodiment;

FIGS. 4A and 4B illustrate isometric views of a lid, in accordance with at least one embodiment;

FIG. 4C illustrates a side view of a lid having the radius in its curved surface, in accordance with at least one embodiment;

FIG. 4D illustrates a front elevation view of a lid in which the thickness is illustrated along with the axial lengths, relative to the curved surface, in accordance with at least one embodiment;

FIG. 4E illustrates a side cross-sectional view of a liquid flow simulation within an embodiment of a manifold in which a lid is positioned to slow and redirect an inlet flow, in accordance with at least one embodiment;

FIG. 4F is a cross-sectional perspective view of a liquid flow simulation within a manifold incorporating a lid having the curved surface, in accordance with at least one embodiment;

FIG. 4G illustrates a cross-sectional side view of a liquid flow simulation with an embodiment of the manifold incorporating a lid having the curved surface, in accordance with at least one embodiment;

FIG. 4H illustrates a cross-sectional side view of an embodiment of a flow simulation for a manifold, in accordance with at least one embodiment;

FIG. 4I illustrates a cross-sectional side view of a manifold, in accordance with at least one embodiment;

FIG. 5A illustrates an example process for using manifold modules and a lid in a manifold of a cooling loop, in accordance with at least one embodiment;

FIG. 5B illustrates a further example process of forming a manifold having a lid for a cooling loop, in accordance with at least one embodiment;

FIG. 5C illustrates an example process for using manifold modules in a manifold of a cooling loop, in accordance with at least one embodiment;

FIG. 5D illustrates a further example process of forming a manifold for a cooling loop, in accordance with at least one embodiment; and

FIG. 6A illustrates an example datacenter system, according to at least one embodiment.

FIG. 6B is a block diagram that schematically illustrates a computing system that may be a datacenter or a High-Performance Computing (HPC) cluster, in which at least one embodiment described herein may be used;

FIG. 6C illustrates a computer system, according to at least one example, in which at least one embodiment described herein may be used; and

FIG. 7 illustrates an example network configuration of components that can be used to implement aspects of various embodiments, such as to provide, generate, modify, encode, process, fuse, and/or transmit generated image data, calculated measurements, or other such content.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

The systems and methods described herein may be used for a variety of purposes, by way of example and without limitation, for machine control, synthetic data generation, model training or updating, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational artificial intelligence (AI), generative AI with large language models (LLMs), light transport simulation (e.g., ray-tracing, path tracing, etc.), collaborative content creation for 3D assets, cloud computing and/or any other suitable applications.

Disclosed embodiments may be comprised in a variety of different systems such as, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems for performing generative AI operations using LLMs, systems for performing light transport simulation, systems for performing collaborative content creation for 3D assets, systems implemented at least partially using cloud computing resources, and/or other types of systems.

A problem addressed herein is to split liquid cooling loop into multiple separated (or segmented) liquid cooling loops, in a tight space, where it may not be possible to locate a regular or standard (and fixed) length liquid cooling manifold, where assembly tools may not have access, and where a requirement for manifolds made from copper exists to avoid galvanic corrosion. Each of the separated liquid cooling loops may be terminated with a part of the manifold, when all of the multiple cooling loops are assembled together to make the manifold. The manifold may be referred to herein, interchangeably, as a cooling manifold or a liquid cooling manifold. While a manifold may be made from a single block of a regular or fixed length, to which server-based liquid cooling loops may be connected, a liquid cooling manifold herein may allow a split of a liquid flow into three separate cooling loops, using a compact design manifold, as described all throughout herein, to promote guided and fully-developed flow. The design herein ensures that there is no stagnant areas near caps and may also prevent erosion or corrosion. The layers of segmented liquid cooling manifold may promote guided and fully developed flow, and may prevent stagnant areas and erosion or corrosion in the liquid cooling loops. The manifold modules represent a Lego®-structure of blocks to provide a cooling manifold that allows for compact design, without need for horizontal connections or use of brazing as connection between copper pipes or manifolds. Each of the segmented liquid cooling loops may be terminated with a part of the manifold, when the segmented liquid cooling loops are assembled together to provide the manifold.

The disclosure herein may address the problem described by a liquid cooling system which is capable of use with stacked printed circuit boards (PCBs). The disclosure herein may be directed toward a configurable manifold system that uses different body portions that may be stacked to provide for different cooling configurations. As a whole, the manifold is an arrangement that may include a series of connectable sub-components, referred to herein as manifold modules, that may be stacked and coupled together. The arrangement of the manifold modules may enable a custom stacked configuration of a manifold that may be adjusted based on available space for different PCBs or configurations of PCBs. The manifold may include a variety of different tunable components that may be particularly selected based at least in part on flow characteristics of media through the manifold. For example, different inlet and/or outlet flow diameters of the manifold modules may be selected to accommodate different cooling flow rates, pressure drops, and the like for the manifold. In another example, an interior manifold cross-section may also be selected based on cooling parameters. In at least one other example, one or more seals may be used between mating interfaces for the manifold modules and one or more threaded fasteners may be used to secure the stacked parts together. The manifold modules may also include guiding pins and/or other structures to facilitate alignment and coupling. Accordingly, systems and methods herein may be used to build manifolds with a variety of different parameters based on associated cooling loops for stacked board cooling systems.

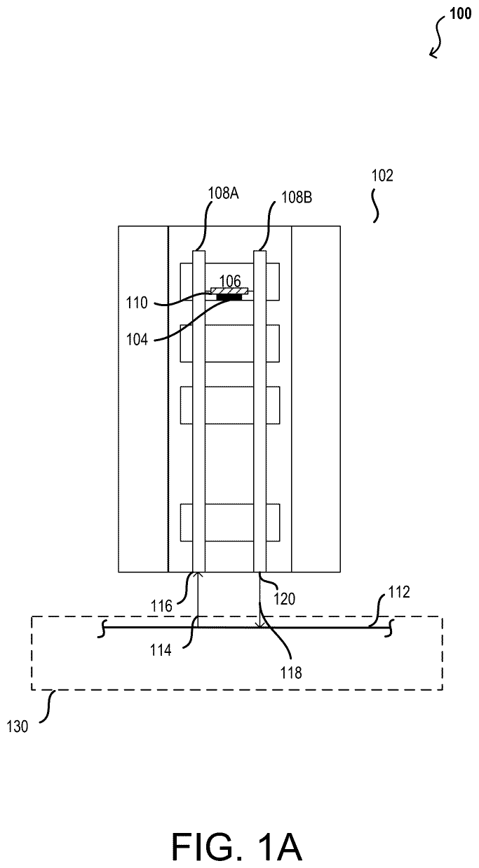

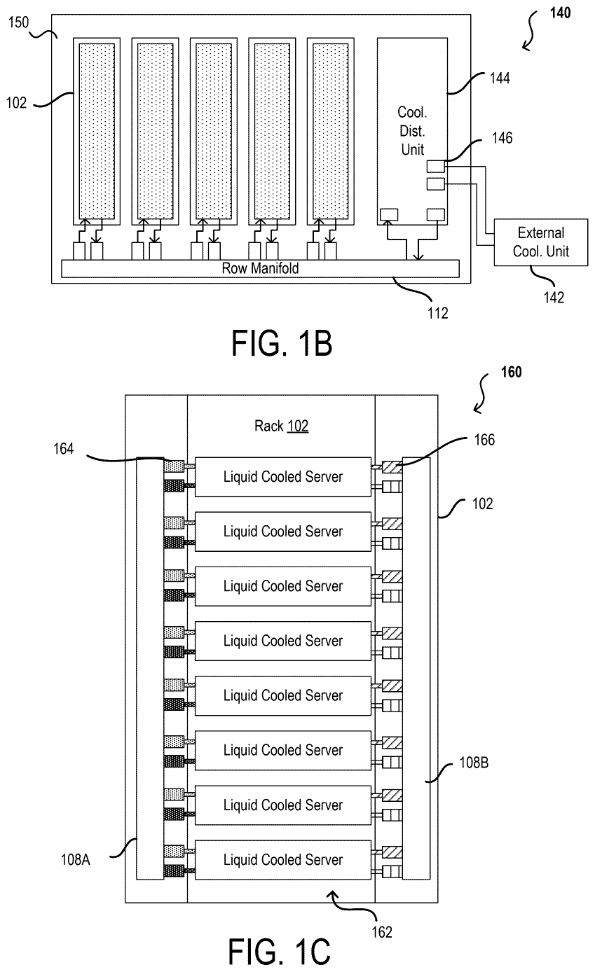

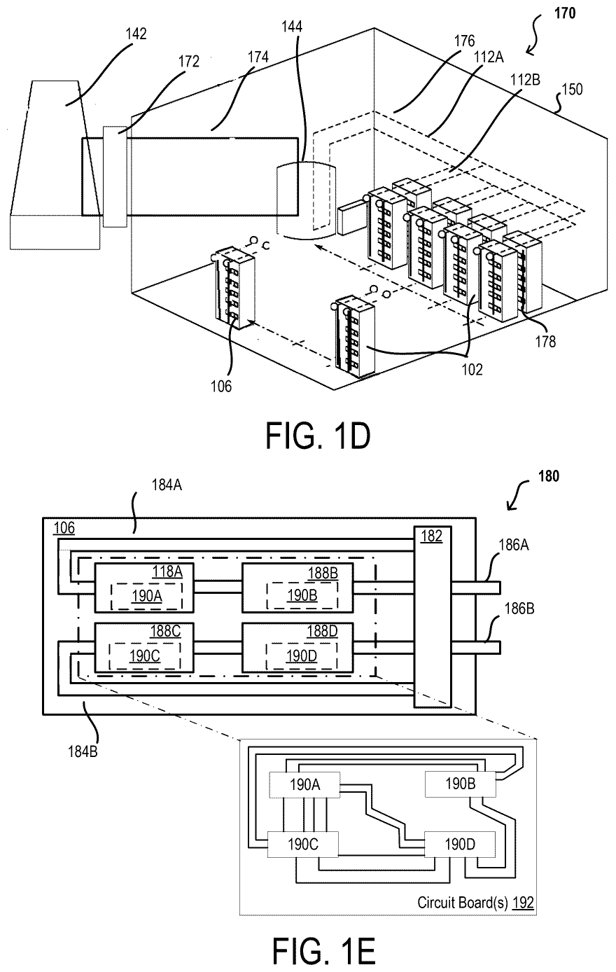

FIG. 1A illustrates an environment 100 for a liquid cooling system that is subject to a customizable and modular manifold in a datacenter, in accordance with at least one embodiment. A manifold module may be a structure having a passage provided for a cooling liquid to flow through, as part of a supply or return of a cooling liquid for a cold plate and as part of a liquid cooling system. A manifold (within the context of a customizable and modular manifold) may be an arrangement of manifold modules provided in a manner that interconnects the passages of the arrangement of manifold modules to allow cooling liquid to flow through the arrangement of manifold modules, as part of a supply or return of a cooling liquid between multiple stacked cold plates and a liquid cooling system. The manifold may include a lid coupled to a manifold module and may include a curved surface of the lid that is positioned within the passage. The curved surface may be configured to receive and direct an inlet flow away from a stagnant flow space in the manifold. The manifold may allow parallel supply or return of a cooling liquid to the stacked cold plates. The manifold may include manifold modules of different physical shapes that may represent customizable and modular configurations in the liquid cooling system.

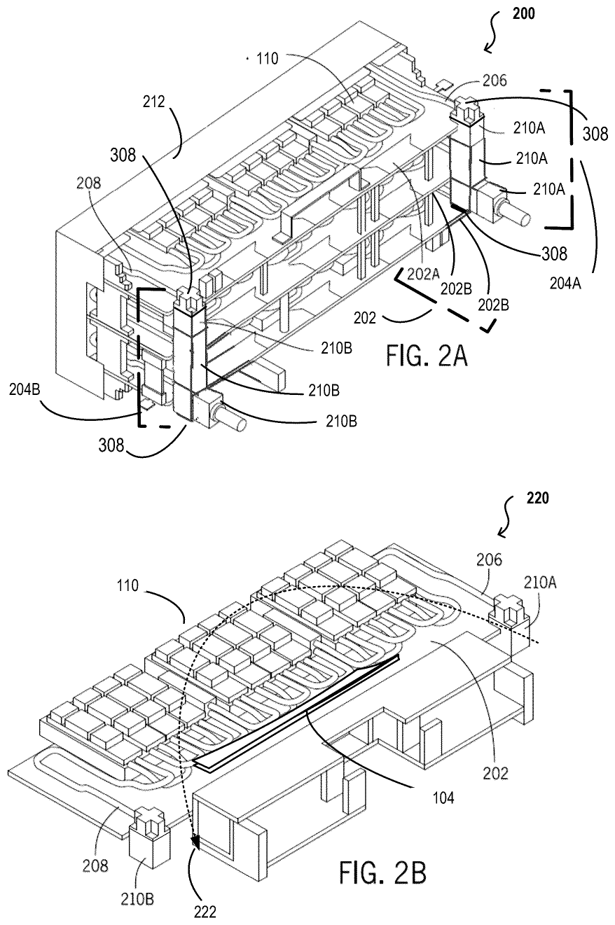

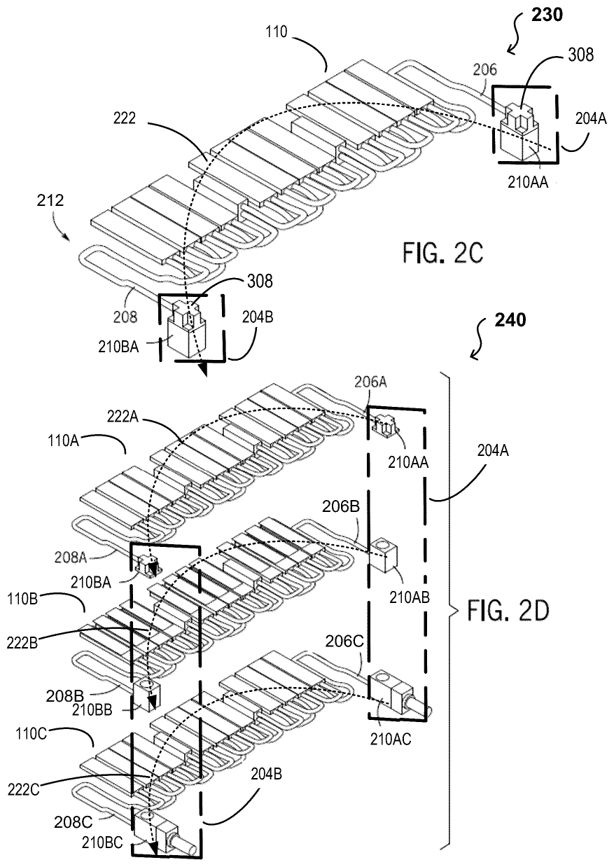

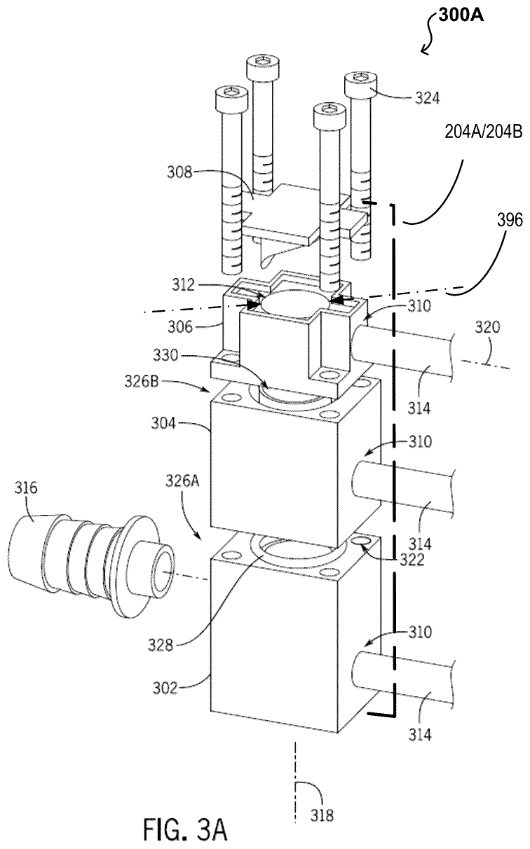

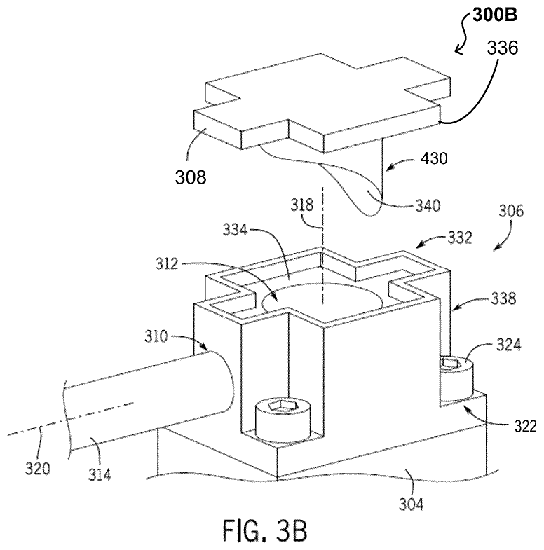

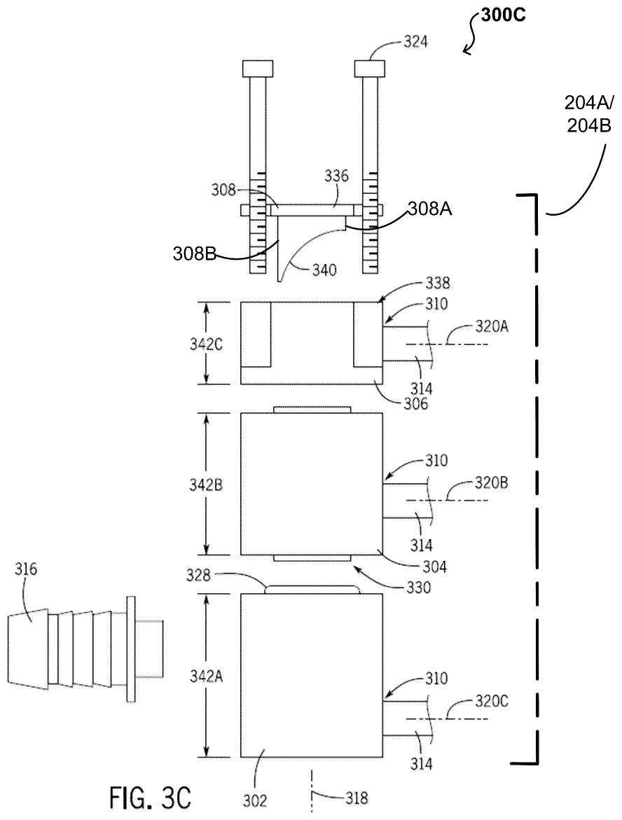

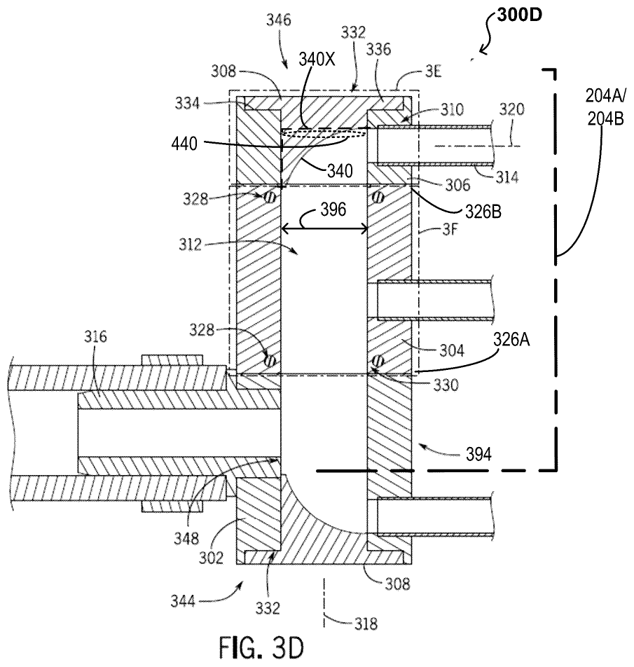

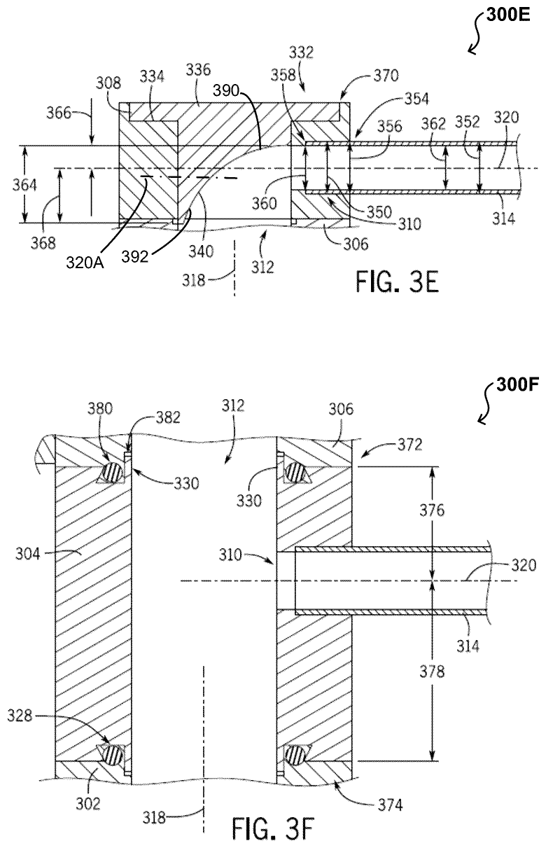

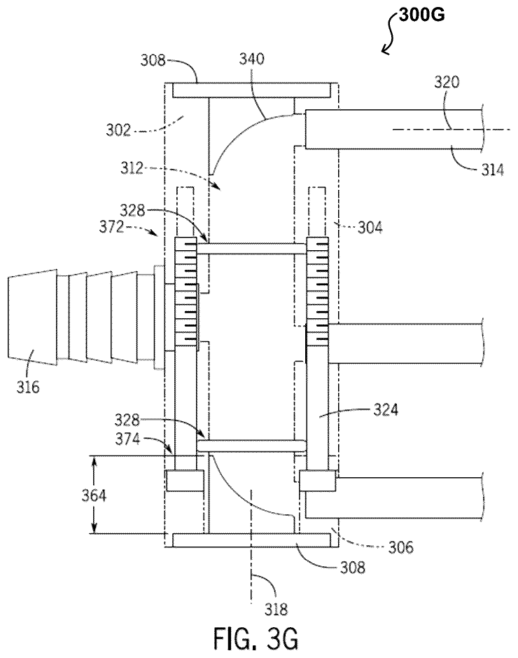

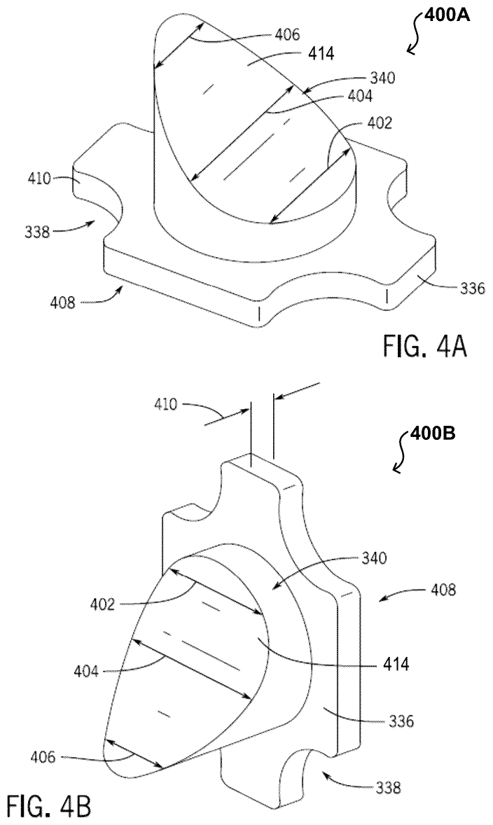

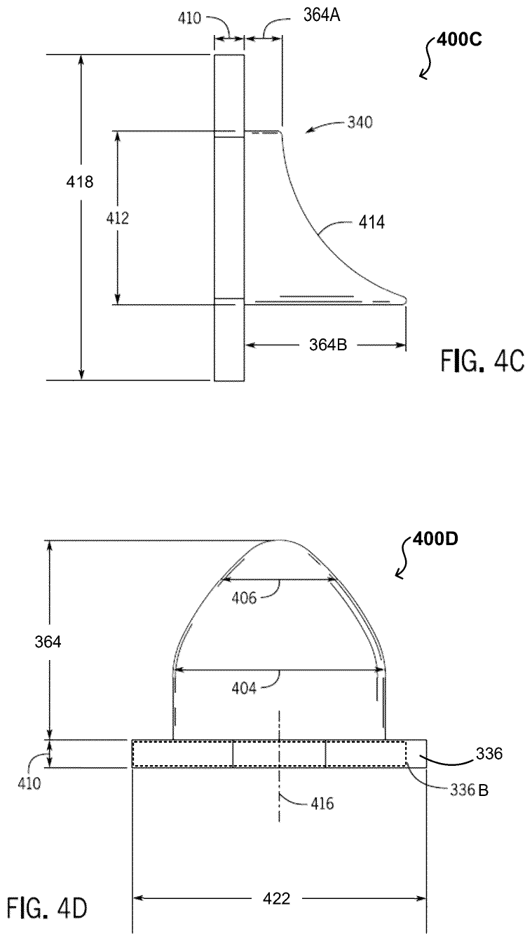

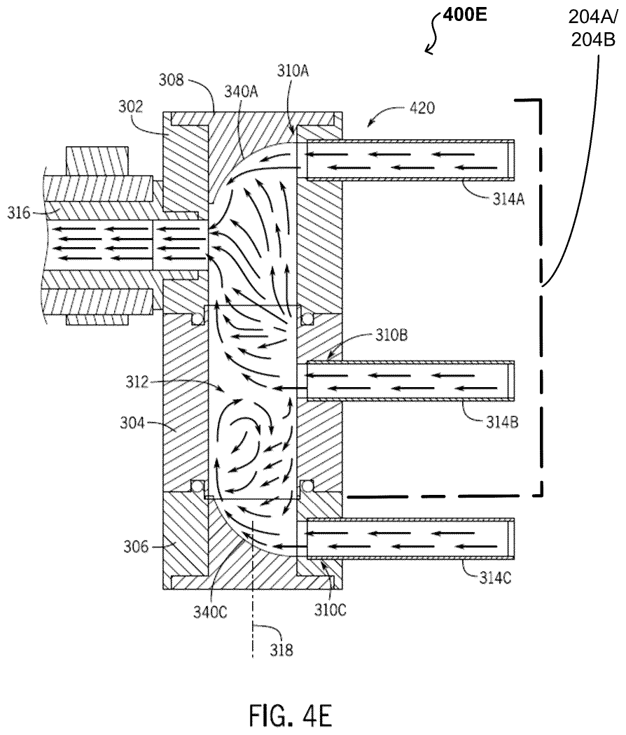

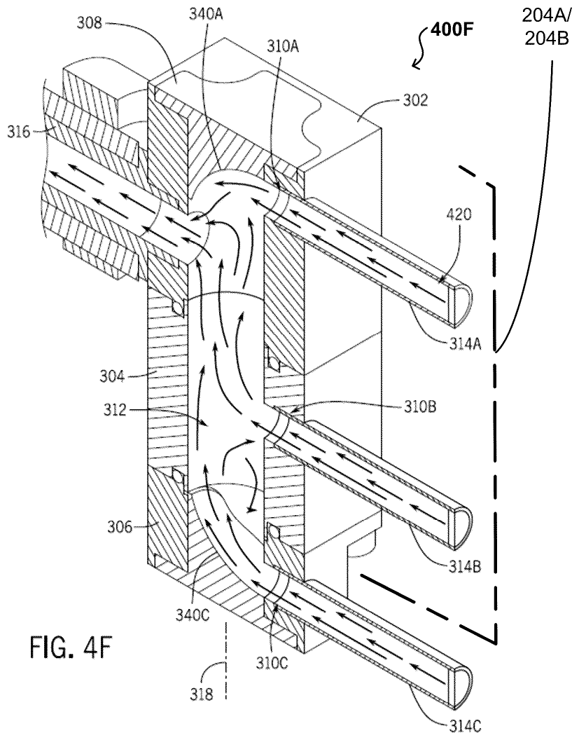

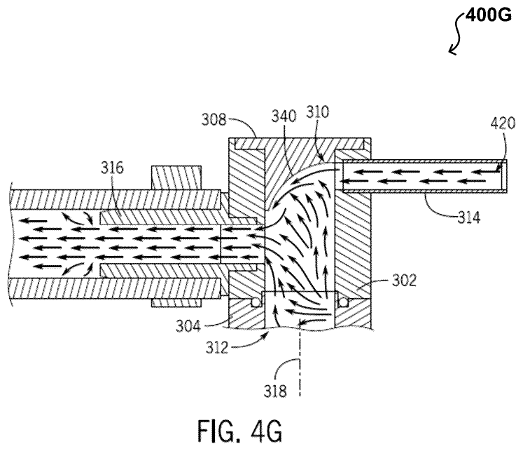

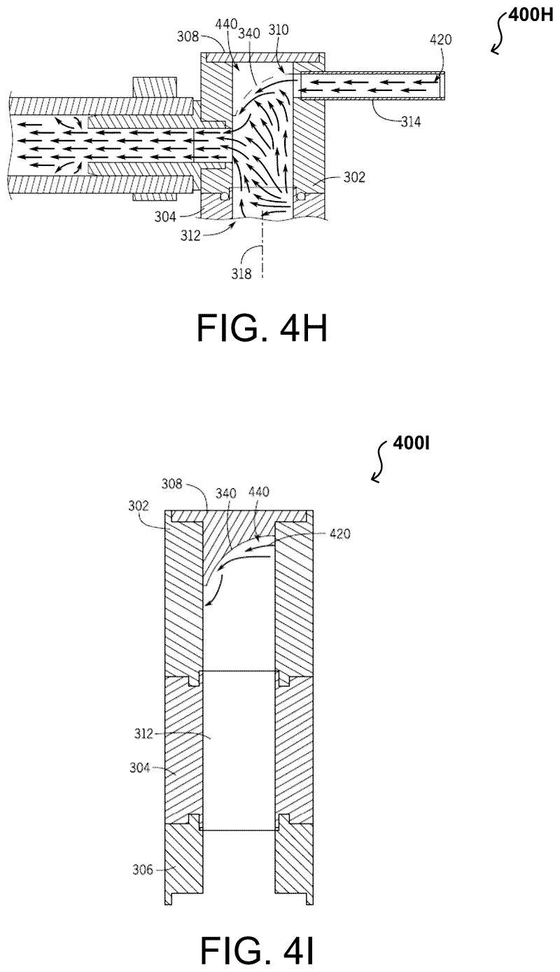

The manifold herein may apply at least at a rack-level (as described with respect to one or more of FIGS. 1A to 1C) and at a server tray or box-level (as described with respect to one or more of FIGS. 2A to 2D). For example, the environment 100 of FIG. 1A may include a rack 102 that may house a number of electronic components 104 (e.g., processing units, switches, and other computing devices) in a stacked configuration within one or more server trays or boxes 106. The rack 102 may be part of multiple racks in a datacenter (such as in FIG. 1B). Each of the server trays or boxes 106 and/or the electronic components 104 may be associated with manifolds 108A, 108B, which may include a manifold 108A for inlet (e.g., a supply manifold) and a manifold 108B for outlet (e.g., a return manifold), to provide a cooling fluid to dissipate heat away from the one or more electronic components 104. The manifolds 108A, 108B may be coupled to one or more cold plates 110 associated with the one or more electronic components 104 to support the dissipation of heat from the one or more electronic components 104. The manifolds 108A, 108B are at a rack-level and may be provided by the manifold modules described further in FIGS. 3A to 4I.

For instance, any of the manifolds 108A, 108B at the rack-level may include respective passages and may be formed of an arrangement of manifold modules. Although illustrated as a linear structure of a singular manifold, the illustrated manifolds 108A, 108B may individually include an arrangement of manifold modules that may be stacked to support each of the one or more server trays or boxes 106. A manifold 108A, 108B may include a first manifold and may include a lid (detailed in FIG. 3A). For instance, the lid may be at a top of the manifolds 108A, 108B to prevent cooling fluid from exiting the manifolds 108A, 108B. The first manifold may include a first passage and the lid may be removably coupled to the first manifold. The lid may include a curved surface (detailed in FIGS. 3A, 3B, 3E, for instance) therein to be positioned within the first passage. The curved surface may be configured to receive and direct an inlet flow away from a stagnant flow space of the manifolds 108A, 108B, as also detailed with respect to one or more of FIGS. 3A to 4I. As there may be many manifold modules arranged together and as there may be at least a top lid with the manifold modules, the arrangement of manifold modules in different stacks can support multiple stacked cold plates and may represent customizable and modular cooling manifolds for a datacenter.

In a further example, the manifolds 108A, 108B may include multiple individual manifolds arranged at different locations throughout a server tray or box 106, throughout a rack 102, or throughout a datacenter (as in FIG. 1B). The locations may include vertical or horizontal orientations for the manifolds 108A, 108B. In one example, the manifolds 108A, 108B may be arranged at sides of the rack 102 to provide improved access to the interior of the rack 102. Additionally, the manifolds 108A, 108B may be positioned on opposite sides of the rack 102. FIG. 1A also illustrates that the manifolds 108A, 108B may be coupled to one or more row manifolds 112 of a datacenter. The manifolds 108A, 108B at a rack-level, along with one or more row manifolds 112, may be part of a secondary cooling loop. The one or more row manifolds 112 may be associated include separate inlets and outlets than the manifolds 108A, 108B at the rack-level, in one example. Further, the one or more row manifolds 112 may also benefit from the customizable and modular cooling manifolds for a datacenter described herein.

The one or more row manifolds 112 may include a row outlet 114 to a source inlet 116 of one manifold 108A and may include a row inlet 118 to a source outlet 120 of another manifold 108B. The source inlet 116 may allow the cooling fluid along a length of one of manifold 108A of a rack 102 and to one or more cold plates 110. A heated cooling fluid, after receiving dissipated heat from electronic components 104, may pass through a different manifold 108B of the rack 102 till it reaches the source outlet 120 to return to the one or more row manifolds 112. The heated cooling liquid may be cooled and reused. For instance, the secondary cooling loop may exchange heat with a primary cooling loop that may exit the datacenter to dissipate collected heat outside the datacenter. The one or more row manifolds 112, the manifolds 108A, 108B of the rack 102 (and of other racks), the cold plates 110, and any further manifolds such as at the server tray or box-level (within the server trays or boxes 106) may all be part of a liquid cooling system 130 used within the datacenter. Each of such manifolds may individually be a customizable and modular manifold having manifold modules and at least on lid with at least a curved surface to receive and direct an inlet flow away from a stagnant flow space of a respective manifold.

The rack 102 may represent an end location in a datacenter for the liquid cooling system 130. Although, a cold plate 110 may be a point in a datacenter at which heat is removed from an electronic component 104. The illustrated rack-mounted ones of the manifolds 108A, 108B, or one or more row manifolds 112 and with other server tray or box-level manifolds (such as illustrated in FIGS. 3A-4I) may include one or more manifold modules and the aforementioned lid having at least one curved surface, as part of the customizable and modular configurations for the manifold. The manifold modules and the lid may include one or more aligned fittings to permit a variety of different customizable and modular configurations.

The aligned fittings may be particularly selected to accommodate tight spacing issues and/or to adapt to changes in stack configurations within racks or server trays or boxes in a datacenter having the rack 102. In one example, the customizable and modular configurations may allow alignment along a common flow axis for the manifold modules and the lid that may be coupled together via one or more fasteners. There may be additional lids in the customizable and modular configuration. Each lid may include curved surfaces to reduce erosion-corrosion, reduce stagnant flow, and/or to facilitate flow along a variety of different flow paths. The customizable and modular configurations for the illustrated manifolds 108A, 108B, 112 and with other manifolds (such as illustrated in FIGS. 3A-4I) allow improved serviceability and modification in areas with tight space limitations.

In one example, a first material and a second material may be determined to be used with individual ones of the lids and with individual ones of the manifold modules. The determination may be based in part on an erosion or corrosion reduction capability in the first material relative to the second material. The first material may be used to form individual ones of the lids by a coating, lining, cladding, or application of sleeves of the first material to a curved surface 340 (in FIG. 3E) of the lids. The second material may be used to form individual ones of the manifold modules by a coating, lining, cladding, or application of sleeves of the second material to an internal surface of the manifold modules 302, 304 (in FIG. 3D).

FIG. 1B illustrates a datacenter 140 having a liquid cooling system of FIG. 1A that may be used with one or more racks, in accordance with at least one embodiment. The datacenter 140 illustrates multiple racks 102 within an area 150, where the racks 102 may be associated with all aspects of a liquid cooling system 130, as in FIG. 1A. In addition, FIG. 1B illustrates further details of a primary cooling loop to exchange heat with a secondary cooling loop and to exit the datacenter to dissipate collected heat outside the datacenter 140. The exchange of heat may occur using a cooling distribution unit (CDU) 144 and may be controlled by controls boards 146 which may receive data from a variety of sensors associated with the liquid cooling system 130. For example, the one or more sensors may provide flow rate data, cooling pressure data, status of auxiliary systems, and/or the like which may be associated with a cooling fluid. The dissipation of collected heat outside the datacenter 140 may occur using an external cooling unit 142 that may be a cooling tower. At least part of the CDU 144 and the external cooling unit 142 may form part of a primary cooling loop for the datacenter 140. FIG. 1B also illustrates the one or more row manifolds 112 that can send/receive cooling fluid to/from the CDU 144 and to and from the racks 102 as part of the secondary cooling loop.

FIG. 1C illustrates control aspects 160 of a secondary cooling loop of FIG. 1A that may be used with one or more racks, in accordance with at least one embodiment. The control aspects 160 may include the use of an inlet valve 164 for allowing cooling liquid into individual ones of the servers 162 of a server tray or box 106, from a manifold 108A. The control aspects 160 may also include the use of an outlet valve 166 to return heated cooling liquid to a different manifold 108B of the rack 102. The inlet valve 164 and the outlet valve 166 may be used to control cooling for the electronic components 104.

In an example, sensors may be provided for the electronic components 104 or in any part of the secondary cooling loop to capture information about temperature, fluid flow, or other such aspects of the liquid cooling system 130 and/or of rack 102. The sensors may capture information that may include internal and/or external information, relative to the liquid cooling system 130 and to individual ones of the servers 162. The cooling liquid associated with the manifolds 108A, 108B may be used to remove an amount of heat from servers 162, but due to factors such as varying load and external temperature fluctuations, temperatures at various locations may change. The temperatures at various locations may reach or exceed temperature limits at which these electronic components 104 can continue to operate as intended. The inlet and outlet valves 164, 166 may be used, in part, to ensure that temperatures at specific locations remain below an acceptable limit, where those locations may relate to junction temperatures or core temperatures for an electronic component 104 (e.g., a processor unit, memory module, or power supply).

In at least one embodiment, fluid quality may be monitored and controlled at a rack level using one or more of the manifold assemblies or sensors herein. The sensors may include inline flow sensors that can be associated with any of the illustrated manifolds and the discussed manifolds in FIGS. 1A-4I. Different racks and servers may have different flow characteristics, such as different diameter flow channels in direct-to-chip cooling boards. In support of these differences, different manifold sizes and/or different manifold properties, representing different cooling configurations, may be used from for a manifold to match the racks and servers. Different manifold configurations may apply to the control aspects 160 in FIG. 1C and may be based, at least in part, on different manifold modules associated to form the manifold that may be used in its customizable and modular configurations. In this manner, manifolds may be designed to accommodate unique configurations of a given rack 102 while still using one or more non-unique components for simplicity in sizing, selection, and maintenance. The different manifold properties may include a predetermined flow rate, a predetermined pressure difference, a predetermined component size, or a predetermined spacing associated with stacked printed circuit boards (PCBs) to be coupled to the individual segment cooling loops.

Datacenters and other networking systems may include connections between datacenters, switch systems, servers, racks, and devices in order to provide for signal transmission between one or more of these elements. These connections may be made using cables, transceivers, interconnects, interposers, and connector assemblies. For high bandwidth applications and/or connections over long distances, high powered optical communications may be preferred to ensure signal transmission integrity.

FIG. 1D illustrates further aspects 170 of a liquid cooling system of FIG. 1A that may be used with one or more racks, in accordance with at least one embodiment. In at least one embodiment, an area 150 may be one or more rooms of a datacenter. The area 150 may have racks 102 to house one or more servers 162 within one or more server trays or boxes 106. The area 150 illustrated may be supported by a cooling tower, represented as an external cooling unit 142 in FIG. 1B. The cooling tower may be located external to the area 150 and external to a datacenter. The cooling tower may be supported by a chiller 172 to provide additional cooling. A cooling tower may be able to dissipate heat from within a datacenter by acting (such as by acting as a heat exchanger) on a primary cooling loop 174. A CDU 144 may be used between a primary cooling loop 174 and a second or secondary cooling loop 176 to allow extraction of heat from a second or secondary cooling loop 176 to a primary cooling loop 174.

A secondary cooling loop 176 may access various plumbing into a server tray as required, in an aspect. One or more of the primary cooling loop or the secondary cooling loop, illustrated as line drawings, may include plumbing features not illustrated but apparent to person of ordinary skill. In one example, flexible polyvinyl chloride (PVC) pipes may be used along with associated plumbing to move fluid along in each of the secondary cooling loop 176 and the primary cooling loop 174. One or more pumps may be used to maintain pressure differences within secondary cooling loop 176 and the primary cooling loop 174. The pressure difference may allow movement of a cooling fluid according to temperature sensors in various locations, including in a room, in one or more racks 102, and/or in server boxes or server trays within one or more racks 102.

A cooling fluid in a primary cooling loop 174 and in a secondary cooling loop 176 may be at least water and an additive. An additive may be glycol or propylene glycol. In operation, each of a secondary cooling loop 176 or a primary cooling loop 174 may have their own cooling fluid. A cooling fluid in secondary cooling loop 176 may be proprietary to requirements of components in a server tray or in associated racks 102. A CDU 144 may be capable of sophisticated control of cooling fluid, independently or concurrently, within a secondary cooling loop 176 or a primary cooling loop 174. A CDU 144 may be adapted to control flow rate of cooling fluid so that the cooling fluid is appropriately distributed to extract heat generated within associated racks 102.

In at least one embodiment, part of a secondary cooling loop 176 within a room or area 150 may be referred to as room manifolds 112A. The room manifolds 112A may feed row manifolds 112B of the secondary cooling loop 176. The row manifolds 112B may feed rack manifolds 178 of each of the racks 102. Modular cooling manifolds described herein may be used instead of one or more of such room, rack, and row manifolds. In one example, modular cooling manifolds described herein may be used at connections between multiple manifolds or between a manifold and a cold plate.

FIG. 1E is an illustration of server aspects 180 of a liquid cooling system, in at least one embodiment. The server aspects 180 may include server-level features and may include a server tray or box 106 having at least one server manifold 182 to allow entry and egress of a cooling media of a secondary cooling loop, with respect to a rack manifold 178 of a rack 102. The server manifold 182 may include separate channels or manifolds for inlet and for exit of cooling media of the secondary cooling loop 176. The server aspects 180 illustrated may have distinct secondary cooling loops 184A, 184B, within the server tray or box 106.

Secondary cooling fluid may enter to the server manifold 187, from a rack manifold 178, via an inlet pipe 186A and may exit via outlet pipe 186B. The secondary cooling fluid may travel through one or more cold plates 188A-188D, and exit to the server manifold 187. This represents at least one or multiple secondary cooling loops 184A, 184B within the server tray or box 106. These multiple secondary cooling loops 184A, 184B may be an extension of the secondary cooling loop 176 interfacing with the primary cooling loop 174 as they provide the same or substantially the same secondary cooling fluid from the secondary cooling loop 176 to the cold plates 188A-188D. The cold plates 188A-188D may be associated with at least one of the electronic components 190A-190D. In addition, while illustrated as different cold plates, the illustrated cold plates 188A-188D may be part of a large single cold plate structure that has integrated contact points that are specifically over the underlying electronic components 190A-190D. The electronic components 190A-190D may include processors, memories, and switches or regulators on one or more circuit boards 192. QPUs configured to perform one or more operations associated with a quantum algorithm. In one example, the processors may include central processing units (CPUs), graphics processing units (GPUs), data processing units (DPUs), quantum processing units (QPUs), plurality of parallel processing units (PPUs), and application-specific integrated circuits (ASICs). In some examples, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

In at least one embodiment, even though illustrated as having one inlet and one outlet or exit between the cold plates 188A-188D, there may be multiple intermediate lines, such as intermediate manifolds associating a cold plate with a respective line of the multiple secondary cooling loops 184A, 184B within a server tray or box 106. The intermediate lines directly couple a cold plate to a manifold which may include the customizable and modular manifolds described herein.

FIG. 2A illustrates a system 200 of stacked printed circuit boards (PCBs) with at least one manifold assembly, in accordance with at least one embodiment. FIG. 2A illustrates customizable and modular manifolds at a server-tray or box-level. The stacked PCBs may include three PCBs 202, with each of the PCBs being associated with an independent one of the cold plates 110 (only one is illustrated in FIG. 2A and all three are illustrated in the exploded details in FIG. 2D). Each cold plate 110 may extend throughout provided dimensions of each of the PCBs 202. A cold plate 110 may provide direct or indirect contact cooling to one or more of the electronic components on each of the PCBs 202. In one example, when a GPU card is an electronic component 104, a cold plate 110 may be provided to extend over an entire physical format of the GPU card. The system 200 may be provided within an enclosure 212 that may be used with a server tray or box 106, although the system 200 may be provided directly within the server tray or box 106.

There may be channels provided within a cold plate 110 to allow concentration of a cooling fluid or the flow of a cooling fluid over areas of an electronic component 104 having process or memory-intensive features. Each of the PCBs 202 may be in a card format and may be enveloped and shielded to protect the electronic components 104 therein. An electronic component 104 may be a chip or semiconductor device format, such as a CPU, a GPU, a DPU, a QPU, a PPU, an ASIC, or a switch in a packet or circuit that is attached to one of the PCBs 202. An electronic component 104 or each of the PCBs 202 herein may also be or include network devices such as switches, network adapters, or data processing units (DPUs). Each of the PCBs 202 may have multiple electronic components 104 mounted thereon. The electronic component 104 may include a multiple die (such as a multi-core processor device) format. The cores may be stacked or distributed. A single one of the cold plates 110 may be associated with a single one of the electronic components 104 or with the entire PCB of each of the PCBs 202 illustrated.

A cold plate 110 may include an inlet 206 (e.g., a supply inlet, plate supply inlet, etc.) and an outlet 208 (e.g., a return outlet, plate supply outlet, etc.) coupled to one or more respective ones of the manifolds 204A, 204B that are server-mounted for providing supply and return of the cooling fluid. The respective ones of the manifolds 204A, 204B may provide cooling fluid to a number of different one of the cold plates 110. For example, two or more cold plates 110 of different PCBs 202 may be able to receive and to return cooling fluid through the manifolds 204A, 204B. As will be apparent from the exploded details in FIG. 2D, the manifolds 204A, 204B may include multiple manifold modules 210A, 210B and at least one lid that (such as a lid 308 in FIG. 3A) may be stacked on each side of the system 200 to form the respective ones of the manifolds 204A, 204B on each side of the system 200.

The cold plates 110 may be stacked vertically to be higher than an associated one of the PCBs 202. For example, a first PCB 202A may be associated with a first cold plate 110A (in FIG. 2D), a second PCB 202B may be associated with a second cold plate 110B (in FIG. 2D), and a third PCB 202C may be associated with a third cold plate 110C (in FIG. 2D). Each cold plate 110 may be associated with its own inlet 206 and outlet 208 coupled to respective ones of the manifolds 204A, 204B of a manifold assembly. The individual ones of the manifolds 204A, 204B may include passages through respective ones of the manifold modules 210A, 210B to allow at least one server cooling loop to service individual ones of the manifolds 204A, 204B. Further, each manifold module 210A, 210B may individually provide a segment cooling loop for its associated first, second, or third PCB 202A, 202B, 202C. Each of the segment cooling loops may contribute heat removal to a server cooling loop.

As illustrated, there may be multiple manifolds, for an inlet 206 and for an outlet 208 to maintain cooling fluid distinctly from heated cooling fluid. In another example, multiple manifolds may include configurations to supply and to return different cooling liquid of two or more segment cooling loops. The different segment cooling loops may be provided by selecting particular manifold modules, such as of specific shapes and corresponding lids to enclose each segment cooling loop. This allows one or more manifolds that may be configured for quick assembly and modularity to fit one or more target locations of a server tray or box 106 (or a server 162 within a server tray or box 106). This also allows individual ones of the manifold modules to include different shapes or dimensions.

In one example, a manifold 204A may be used for supply of cooling fluid and may include a singular supply inlet and multiple manifold module outlets, while a manifold 204B used for return of heated cooling fluid may include multiple manifold module inlets and a single return outlet. In operation, cooling fluid may be provided to a manifold 204A (and by extension to its individual manifold module 210A) on a supply side, which directs the cooling fluid to an associated first, second, or third cold plate 110A, 110B, 110C via a respective inlet 206. As heat is removed from the electronic components 104 associated with a PCB 202, the outlet 208 may direct heated cooling fluid into a manifold 204B (and by extension, the individual manifold module 210B) on a return side.

The different shapes or dimensions for manifold modules 302, 304 may be predetermined based in part on one or more operating conditions for the manifold or the manifold modules. The one or more operating conditions as used herein may include a predetermined flow rate, a predetermined pressure difference, a predetermined component size, or a predetermined spacing associated with stacked printed circuit boards (PCBs) to be coupled to the individual segment cooling loops. Each of the predetermined flow rate, a predetermined pressure difference, a predetermined component size, or a predetermined spacing associated with stacked PCBs may contribute to a predetermined fluid velocity which is being reduced by the lids at different ends of the manifold modules, in one example. The one or more operating conditions may be predetermined for an outgoing flow from a manifold or may be predetermined for an incoming flow to the manifold. The different manifold sizes may include different shapes or dimensions that are internal or external for the manifold modules.

FIG. 2B is a view 220 of a single PCB with a single cold plate and may be from the system 200 in FIG. 2A, in accordance with at least one embodiment. The inlet 206 and the outlet 208 for cooling fluid are illustrated and are coupled to respective ones of the manifolds 210A, 210B for supply of cooling fluid and for return of heated cooling fluid. The configuration illustrated may be used to pass cooling fluid over one or more electronic components 104, via the provided cold plate 110, to dissipate heat away from the electronic component 104 of the PCB 202. Although partly illustrated, the electronic component 104 may be fully under the cold plate 110.

The configuration illustrated also includes the first (that may be a topmost) ones of the manifold modules 210A, 210B to provide the cooling liquid to the cold plate 110. The first ones of the manifold modules 210A, 210B may have a specific shape that may be different from a second (that may be a middle) or third (that may be a lowermost) one of the manifold modules 210A, 210B. The reference to topmost, middle, and lowermost may be based on a location of the manifold modules (or orientation of a manifold having the manifold modules) relative to each other and in a vertical direction with respect to a vertical axis (such as axis 318 in FIG. 3A) of a rack 102. The location of the manifold modules may be changed (such as reversed or upside down without affecting a scope of the disclosures herein) and so, the first manifold module may be a topmost or lowermost manifold module depending on the location provided or depending on the orientation provided. In one example, the second or third ones of the manifold modules 210A, 210B may have a same shape and may be interchangeable. In another example, the first or third ones of the manifold modules 210A, 210B may include lids. The manifold modules 210A, 210B may support or may be part of individual segment cooling loops 222A-222C, along with the inlet 206 and outlet 208 coupled to an individual one of the manifold modules 210A, 210B (as illustrated in FIG. 3A).

FIG. 2C is a view 230 of the cold plate 110 coupled to respective ones of the manifold modules 210AA, 210BA, which are illustrated with lids 308 on the top (as in FIG. 3A) and below (as in FIG. 3D). Various tubulars may be associated with the cold plate 110 to route the cooling fluid through different heat producing zones to remove heat from the underlying PCB. As illustrated, a segment cooling loop 222A-222C may include the inlet 206 and outlet 208 coupled to the cold plate 110. As also illustrated in FIGS. 2B and 2C, a cold plate 110 may include multiple smaller cold plates or cold plate sections that may be of different shapes, as illustrated. Although FIG. 2C illustrates a single one of the manifold modules 210AA, 210BB, the provision of a lid above and below the single one of the manifold modules 210AA, 210BB may allow a compactness in the individual ones of the manifolds 204A, 204B used with a single level of a stack of cold plates. In this manner, it is possible to isolate stacks of cold plates within a limited space in a rack or a server tray or box.

FIG. 2D illustrates an exploded view 240 of a stacked set of cold plates, in accordance with at least one embodiment. There may be multiple cold plates, but three cold plates 110A-110C may represent three different segment cooling loops 222A-222C. Each segment cooling loops 212A-212C may be coupled to different ones of the manifold modules 210A, 210B for the respective ones of the manifolds 204A, 204B. Each of the individual segment cooling loops 222A-222C may have one or more inlets 206A-206C and/or outlets 208A-208C. Accordingly, a segment cooling loop 222A, 222B, 222C may refer to a cooling loop formed by the corresponding ones of the manifold modules 210A, 210B between different ones of the manifolds 210A, 210B.

In one example, a first (such as a topmost) segment cooling loop 222A may be associated with first ones of the manifold modules 210AA, 210BA, while a second (such as a middle) segment cooling loop 212B may be associated with second ones of the manifold modules 210AB, 210BB, and a third (such as a lowermost) segment cooling loop 212C may be associated with third manifold modules 210AC, 210BC. As apparent from the illustration, there may be multiple second segment cooling loops 212B and at least one third segment cooling loop 212C may be open to the rack-mounted manifolds to return fluid directly to a rack-mounted manifold. The first segment cooling loop 222A may have lids associated with the first ones of the manifold modules 210AA, 210BA to allow circulation or looping of a cooling fluid to a return side, from a supply side of the first segment cooling loop 222A. Based at least in part on heat generated (or to be generated), workload performed (or to be performed), dimensions of the datacenter, the rack, and the server trays or boxes, there may be any reasonable number of cold plates and manifold modules considered in a liquid cooling system. Additional design considerations may include cooling flow capacity, space requirements, and/or the like, to determine a number of manifold modules to be used.

FIG. 3A illustrates an exploded view 300A of an embodiment of a manifold having manifold modules, in accordance with at least one embodiment. The illustrated manifold may be one of the manifolds 204A or 204B from FIG. 2A or 2D. Based at least in part on design considerations made for a server tray or box, for a rack, or for a datacenter, a number of manifold modules 302-306 may be determined for association together to provide a manifold 204A, 204B. In this manner, one or more dimensions of the manifold 204A, 204B may be tuned to accommodate available space associated with a PCB stack (as in FIG. 2A). The manifold modules 302-306 may allow a compact manifold to be formed, as also described with respect to FIG. 2C, to be used in a datacenter. A compact manifold may include fewer manifold modules, such as a single manifold module having a lid, as in the case of FIG. 2C. This approach may reduce a number of additional hoses or tubes used to direct and/or receive cooling fluid for an associated rack, which may be unwieldy or unsuitable in tight spaces.

The manifold modules 302-306 may be formed from a variety of materials including metallic materials, polymers, composites, and combinations thereof. Metallic materials, such as brass, copper, titanium, aluminum, stainless steel, or the like may also be used. The use of brass or copper may provide, as a non-limiting example, a readily available and workable manifold module with reduced risk of failures due to events such as galvanic corrosion, which may be present with the use of stainless steel. Additionally, one or more embodiments may use mixed media for the manifold 204A, 204B, including forming certain manifold modules from different materials and/or incorporating liners or sleeves within various bores. For example, a bore within a copper pipe may be lined or clad with a nickel alloy, as one option.

In an example configuration, a manifold 204A, 204B may be formed from a number of different manifold modules 302-306 that may be arranged together so that passages within the manifold modules 302-306 align to form a passage 312 that may be a singular passage. Further, a lid 308 may be coupled to at least a first or a third one of the manifold modules 302-306. The lid 308 may include a curved surface (as in FIGS. 3B and 3D) that may be positioned within the passage 312. The curved surface may be configured to receive and direct an inlet flow away from a stagnant flow space in the manifold 204A, 204B.

The manifold modules 302-306 may have substantially rectangular physical dimensions. That is, a general perimeter of the manifold modules 302-306 may be rectangular, with substantially planar sides and edge connections at approximately 90 degrees. There may be different configurations, such as different polygons, ellipses, spheres, and/or combinations thereof used in the shapes of the manifold modules 302-306. The configurations of the manifold modules 302-306 may be based on at least an ease of manufacturability, interfacing with additional components, and combinations thereof. At least the rectangular configuration in FIG. 3A may facilitate coupling between the manifold modules 302-306 in a stack configuration, by providing sufficient space for apertures to receive one or more fasteners 324.

Each of the manifold modules 302-306 may include openings 310 that may be arranged substantially perpendicular to a passage 312. The passage 312 may have a diameter 396, which may be formed by boring performed through the manifold modules 302-306 to provide the passage 312. The passages in the manifold modules may have a given diameter, which may vary, or which may be continuous along manifold modules 302-306. For example, one of the manifold modules 302-306 may have a larger diameter of its passage than another one of the manifold modules 302-306.

Transitions between the passages of the manifold modules 302-306 may include sloped surfaces, curved surfaces, stepped surfaces, and/or combinations thereof. In FIG. 3A, each of the openings 310 may be along a common side of the manifold modules 302-306. There may be various embodiments that may include other arrangements to the openings 310. For instance, the openings 310 may be along different sides as needed for space and fluid routing considerations. The openings 310 may have a respective one of the first connections 314, which may be used to provide the cooling fluid to the manifold 204A, 204B and/or to remove heated cooling fluid from the manifold 204A, 204B, depending on the configuration. The first connections 314 may be tubular connections, in one example.

In one example, when a manifold 204A, 204B is part of a supply side of a cooling loop, then the openings 310 may be associated with first connections 314 that direct cooling fluid to one or more cold plates and/or other structures used to remove heat from an electronic component. In another example, when a manifold 204A, 204B is part of a return side of a cooling loop, then the openings 310 may be associated with first connections 314 that receive heated cooling fluid from one or more cold plates and/or other structures used to remove heat from an electronic component. There may be various interchangeable uses between the supply and return sides for the manifolds 204A, 204B, but different configurations may also be used depending on the use case for the manifolds 204A, 204B. The first connections 314 may be tubular or outlet connection or may be a source connection, depending on usage of the first connections 314 in a manifold 204A, 204B that is in a return side or in a supply side. One or more of the source connections in the manifold modules may fluidly couple the manifold or individual ones of the manifold modules to an external cooling loop, such as a secondary cooling loop of a rack or server, relative to the segment cooling loops.

A second connection 316 may be coupled to one or more openings (not pictured) to receive or direct (as a fluid into/out of the manifold 204A, 204B. The second connection 316 may be an outlet connection or may be a source connection, depending on usage of the second connection 316 in a manifold 204A, 204B of a return side or of a supply side. For example, a manifold 204A, 204B on the supply side would receive cooling fluid at the second connection 316 from a source (such as a rack-mounted one of the manifolds 108A, 108B, a row manifold 112, or other aspects of a liquid cooling system 130) and a manifold 204A, 204B on the return side would be able to direct heated cooling fluid out of the second connection 316. In an example where the manifold 204A, 204B is on a return side, the second connection 316 may receive heated cooling fluid that is directed into the manifold 204A, 204B from the first connections 314, such as a rack-level or row-level manifold, among other options.

The second connection 316 may be positioned at a variety of different locations, but in the configuration of FIG. 3A, the second connection 316 may be associated with a third manifold module 302. There may be configurations to include the second connection 316 with one or more of the openings 310 of a second manifold module 304 and/or of a first manifold module 306, in addition to, or in place of, the third manifold module 302. For example, the second connection 316 may be positioned to align with the second manifold module 304 instead of, or in addition to, the third manifold module 302. While the illustrated example includes the second connection 316 in a substantially horizontal arrangement (e.g., perpendicular to a passage), there may be other positions for the second connection 316, where the second connection 316 may be positioned at an obtuse or acute angle with respect to the axis 318 of a manifold 204A or 204B.

The manifold 204A, 204B may be axially aligned with a passage 312 therein that is along an axis 318 illustrated. The axis 318 may be perpendicular to a standing plane over which a rack is provided. The axis 318 illustrated may be arranged substantially perpendicular to one or more connection axes 320. There may be an acute or obtuse angle between the axis 318 of the passages and one or more connection axes 320. For example, an angle may be selected to reduce impingement, reduce stagnant flow, direct flow to a particular region, and/or the like. As a result, while there may be examples of horizontal connections at the first connections 314 (which may define a flow path of a perpendicular flow with respect to the axis 318), such examples are for illustrative purposes and are not intended to limit the scope of the present disclosure, as one or more of the first connections 314 may be positioned in non-horizontal configurations.

Each of the manifold modules 302-306 may include apertures 322 extending through at least portions thereof. The apertures 322 may be aligned such that one or more fasteners 324 may extend through respective ones of the apertures 322. In this example, there may be four of such apertures 322 and four of such fasteners 324, but the configuration shown is by way of example and is not intended to limit the scope of the present disclosure and there may be more or fewer apertures 322 and/or fasteners 324. Additionally, while the fasteners 324 are illustrated as being threaded fasteners that may engage mating threads of the associated ones of the apertures 322, additional coupling mechanisms may be used such as press fits, clamps, adhesives, welds, and or combinations thereof.

Further illustrated in FIG. 3A first and second interfaces 326A, 326B between the components. A first interface 326A is illustrated between the third manifold module 302 and the second manifold module 304. A second interface 326B is illustrated between the second manifold module 304 and the first manifold module 306. One or more of the manifold modules may have an associated interface 326A, 326B and may include a seal 328 and/or a lip 330 in the associated one of the first and second interfaces 326A, 326B to facilitate coupling between the components and formation of a passage 312 that may be a singular or continuous passage from the individual passages. The lip 330 may be used to form a portion of a seal groove and/or may be used for alignment purposes. For example, the lip 330 may be referred to as an alignment pin that extends into a mating component to facilitate coupling of the manifold modules together.

In one example, the different manifold modules may stack or otherwise be coupled together using the lip 330 to facilitate coupling between the manifold modules. In this configuration, the seal 328 may be associated with the third manifold module 302, but another seal 328 may be associated with the second manifold module 304. The configuration illustrated is by way of example and different configurations may be used to facilitate different assembly and/or stack of various manifold modules. For example, in certain examples, the second manifold module 304 may be formed with a lip on one end and a recess on another to facilitate stacking. One or more lips and one or more recesses can support the passage 312 formed within the manifold modules 302, 304. Additionally, seals and/or grooves may be formed in the third manifold module 302 and/or the first manifold module 306. In this manner, different numbers of third manifold modules 302, second manifold modules 304, and/or first manifold modules 306 may be coupled together to form manifolds having a variety of different inlet/outlet configurations. The one or more seals 328 may be positioned at the interfaces 326A, 326B between individual ones of the manifold modules 302, 304 to allow the individual segment cooling loops 222A-222C to be stacked vertically within a server tray or box 106 or a rack 102.

In operation, the manifold modules 302, 304, 306 may be aligned and then secured together using the one or more fasteners 324. The seals 328 arranged at different interfaces 326 may be used to prevent leaks and permit formation of the passage 312, which may receive and direct fluid based on a designed operational configuration of the manifold 204A, 204B (e.g., supply or return). The seal 328 may have a diameter that is selected according to the passage diameter and/or spacing limitations associated with the location of the apertures 322. There may be one or more coupling operations that do not include the fasteners 324, such as welding or brazing of the lid 308 to the first or third manifold module 302 or 306. In this manner, a variety of different customizable and module manifolds may be established using individual manifold modules and lids, which may have different dimensional characteristics.

FIG. 3B illustrates an exploded view 300B of an embodiment of a manifold module (such as a first or topmost manifold module 306) with a lid 308, in accordance with at least one embodiment. The exploded view 300B also illustrates that the lid 308 may be positioned over an opening 332 of the first manifold module 306 that may be configured to receive the lid 308. For example, the lid 308 may have dimensions that substantially correspond to dimensions of the opening 332. The lid 308 includes a first surface portion 390 (in FIG. 3E) of a curved surface 340 extending toward an opening 310 that is an outlet or an inlet for cooling fluid (or heated cooling fluid) and formed in the passage 312 and a second surface portion 392 (in FIG. 3E) of the curved surface 340 extending axially lower than the first surface portion and into the passage 312.

There may be orientating features associated with the opening 332, such as adjusting a dimension of a portion so that the lid 308 may only fit in a target orientation. In this example, the opening 332 includes a shoulder 334 to receive and support a lid 308. As illustrated, the lid 308 may have a substantially corresponding perimeter to the opening 332, which may allow insertion of the lid 308 into the opening 332 such that a flat upper surface is formed. The lid 308 may have a top portion 336 and bottom curved portion 430 (in FIG. 3B). The lid 308 may be positioned within the opening 332 so that the top portion 336 is positioned within the opening 332 to engage the shoulder 334, and as a result, there may not be a step of a change in axial elevation between the first manifold module 306 and the lid 308 after the lid 308 is positioned within the opening 332.

In at least one embodiment, the lid 308 may be secured to the first manifold module 306 without fasteners (e.g., non-threadingly secured), and instead, one or more welding or brazing processes may be used. The lack of fasteners, in certain examples, to secure the lid 308 to the first manifold module 306 may include a lack of external fasteners and a lack of fasteners, such as threads, built into the or otherwise formed in the top portion 336, the lid 308, and/or the opening 332. Additionally, the lid 308 may be press fit into the opening 332. There may be examples that may include fasteners and/or fastening components to secure the lid 308 to the first manifold module 306, such as set screws, threaded fasteners incorporated into the lid 308 and/or into a curved surface 340 at a bottom curved portion 430 of the lid 308, or the like. In an example where no fasteners are used, where the lid 308 may be brazed or welded (as examples of being non-threadingly coupled) to the first manifold module 306, there may not be a seal between the lid 308 and the first manifold module 306. Furthermore, there need not be a flat fit between the top portion 336 and the opening 332.

In FIG. 3B, the first manifold module 306 may be coupled to the second manifold module 304 via the fasteners 324. There may be cutouts 338 formed at corners of the perimeter of the first manifold module 306. The cutouts 338 may accommodate the heads of the fasteners 324. The cutouts 338 may be sized to receive the heads of the fasteners 324 while maintaining structural integrity (e.g., pressure retaining capabilities) of the first manifold module 306. For example, a wall thickness near the cutouts 338 may be selected for a target pressure rating and then other components may be sized based on the wall thickness to permit access to the cutouts 338 by the one or more fasteners 324. The cutouts 338 and/or the heads of the fasteners 324 may be omitted, in an example, in favor of an arrangement where the heads are positioned along a surface of the third manifold module 302.

The bottom curved portion 430 (e.g., extension, extending body, etc.) of the lid 308 may include a curved surface 340 that is a radius shaped surface, an arcuate surface, or the like. The curved surface 340 may be used to redirect and guide an inlet flow away from a stagnant flow space while also reducing a velocity of the fluid, thereby reducing a likelihood of erosion-corrosion damage with the manifolds 204A, 204B. As used herein, a stagnant flow space may refer to a space or region where a fluid flow comes to a stop or flows very slowly. The stagnant flow space may include a stagnation point or area where fluid flow velocity is zero.

A manifold for a cooling loop, such as the individual segment cooling loops 222A-222C, may include different manifold modules 210A, 210B to couple together to form a passage 312 for a cooling fluid. Individual outlets or connections 316 of the manifold modules 210A, 210B can form the individual segment cooling loops to direct the cooling fluid from the manifold 204A. The lids 308 at different ends of the passage 312 can reduce a flow velocity of a cooling fluid, by a predetermined threshold and with respect to outgoing flow, at the individual outlets or connections 316. This is in addition to the lids 308 being able to address stagnant flow space that may include a stagnation point or area where fluid flow velocity is zero, with respect to incoming flow of the cooling fluid.

The predetermined threshold may be determined based in part on application of the manifold or the manifold modules. For instance, an application requiring higher workload performance may benefit from a higher velocity flow, while a lower workload performance may benefit from a lower velocity flow. In addition, segments that are closer to a pump may experience higher velocity that may benefit from reduction to prevent corrosion or erosion and other effects from the higher velocity flows. A determination may be made for one or more operating conditions for a manifold or its manifold modules based in part on the application. A determination of different shapes or dimensions of the manifold modules may be made based in part on the one or more operating conditions. The different shapes or dimensions may be internal or external for the manifold modules.

FIG. 3C illustrates an exploded side view 300C of a manifold, in accordance with at least one embodiment. Each of the manifold modules 302-306 may be substantially aligned along the axis 318 of the passage 312. The manifold modules 302-306 may be coupled together via the one or more fasteners 324 to form the manifold 204A, 204B. The manifold modules 302-306 may be of different sizes or configurations. That is, various dimensions for associated with the manifold modules 302-306 may be particularly selected based on a desired operating configuration for the manifold 204A, 204B.

The third manifold module 302 may include a first height 342A, the second manifold module 304 may include a second height 342B, and the first manifold module 306 may include a third height 342C. The respective heights 342A-342C may not be equal and may be particularly selected to accommodate different cooling arrangements. For example, a kit to form the manifold 204A, 204B may include a number of different manifold modules 302-306 with a variety of different heights. The first height 342A may be larger than both of the second height 342B and the third height 342C. The first height 342A and the second height 342B may be equal, while the third height 342C may be smaller than the first and the second heights 342A, 342B, in another example.

Similarly, other dimensions may also be adjusted for the manifold modules 302-306, such as relative positions of the connection axes 320A-320C along the respective lengths 342A-342C. For example, in FIG. 3C, the connection axis 320C is closer to a bottom of the third manifold module 302 when compared to a distance between the bottom of the second manifold module 304 and its connection axis 320B. There may be adjustments to different locations, or include further manifold modules that may be selected, with different connection orientations in order to tune or adjust flow parameters.

FIG. 3D illustrates a cross-sectional side view 300D of a passage formed from the manifold modules. There are three manifold modules coupled together to provide the manifold 204A, 204B, way of non-limiting example as more or fewer manifold modules may be used. The manifold 204A, 204B may include a pair of lids 308, one at a first manifold module 306 and another at a third manifold module 302. Together, the lids 308 form a sealed passage 312 for directing cooling fluid to/from one or more cold plates and to/from one or more liquid cooling systems 130. Each of the lids 308 may be secured to a respective manifold module via one or more connections, such as a welding, brazed connection, or one or more fasteners. The lids 308 may be positioned within respective openings 332 to form a flat surface at each of the top and bottom 344, 346 of the manifold 204A, 204B. The lid 308 may be installed within a respective opening 332 such that the top portion 336 of the lid 308 engages the shoulder 334, thereby blocking further downward axial movement of the lid 308 along the axis 318 of the passage 312. The lid 308 may then be secured to the associated manifold module to block or otherwise restrict outward fluid flow.

The curved surface 340, as part of the bottom curved portion 430 may extend into the passage 312. The curved surface 340 may be positioned at a predetermined location with respect to the axis 320 in order to direct and/or guide a flow of cooling fluid toward or away from an opening 348 that provides the second connection 316. For example, when used on a return side such as in the manifold 204B, the curved surface 340 may be such that an inlet flow of heated cooling fluid from one or more cold plates, through the first connections 314, may contact the curved surface 340. The curved surface 340 may reduce a velocity of the flow while also reducing a likelihood of stagnant flow in the manifold 204B. Similarly, the curved surface 340 may direct or otherwise guide the inlet flow toward to a target location, such as the opening 348.

Each of the manifold modules 302-306 may include individual passages, generally marked as 394, to contribute to the passage 312 of the manifold 204A/204B. There may be different ones of the seals 328 arranged at certain interfaces, described in connection with at least FIG. 3A. Their relative positions may be selected based on different operational parameters. In an example, the one or more seals 328 may be positioned radially outward of a passage 312 or the passages 394. Similarly, the arrangement of the lips 330 may also be predetermined, such as being a minimum or maximum dimension from the passage 312 or passages 394 (e.g., approximately 5 mm). Other dimensions may be used within the scope of the present disclosure, and moreover, may be selected based on available area, fluid pressures, sealing capabilities, and/or the like.

FIG. 3D taken in conjunction with FIG. 3C also illustrates that a lid 308 may include a first portion 308A (in FIG. 3C) extending perpendicular to the top portion 336 and into the passage 312. The lid 308 may also include a second portion 308B extending perpendicular to the top portion 336 and into the passage 312. The curved surface 340 may be provided to couple the first portion 308A to the second portion 308B. Also, as illustrated, the first portion 308A is of a shorter axial length than the second portion 308B. The axial lengths may be along the axis 318 of the passage 312 of a manifold that is vertical with respect to a rack 102 standing over a surface.

FIG. 3E illustrates a detailed cross-sectional view 300E taken along the area labeled 3E in FIG. 3D. The detailed view illustrates a first manifold module 306 may have the lid 308 positioned within the opening 332 and the first connection 314 may be provided within the opening 310. In an example, the opening 310 may include an opening diameter 350 that is smaller than an outer diameter 352 of the first connection 314. A transition 354 may be provided at an entry point of the first connection 314 into the opening 310, at which point the first connection 314 may include a coupling outer diameter 356 that may be substantially equal to or smaller than the opening diameter 350. This may permit the first connection 314 to be inserted, at least in part, into the opening 310. In at least one embodiment, the opening 310 may be described as including a recess or groove to receive and support the first connection 314. Thereafter, the first connection 314 may be secured to the opening 310, for example using a weld or braze.

One or more of the diameters 350, 352, 356 may be predetermined based on one or more operating conditions. For example, the diameters 350, 352, 356 may be predetermined based on a desired flow rate, a desired fluid velocity, and/or the like. Additionally, the diameters 350, 352, 356 may be different for different openings 310 of the manifold 204A or 204B. For example, a passage 394 of a manifold module closer to the opening 348 may have a smaller diameter than a passage 394 of a manifold module farther away. Additionally, cooling requirements or characteristics associated with the cooling loops may also drive adjustments to the dimensions of the openings 310 and/or the first connection 314.

A second transition 358 may be arranged where the first connection 314 engages the opening 310 at a stepped change to a second opening diameter 360. The second opening diameter is illustrated as being substantially equal to a tubular inner diameter 362, thereby providing a continuous flow path into the passage 312. There may be different diameters between the second opening diameter 360 and the tubular inner diameter 362, which may affect flow rates, fluid velocities, and/or combinations thereof.

A connection axis 320, which may be a radial axis, is illustrated through the curved surface 340 and through a middle of the opening 310. The middle of the opening 310 may be axially higher than a midpoint 320A of the curved surface 340. A midpoint 320A may be determined based at least in part on a straight line segment provided between ends of the curved surface 340 and may be taken from a midpoint of the line segment as an approximation of the midpoint 320A. In another example, the midpoint 320A may be a point at which bisectors of the curved surface 340 may intersect. In another example, the midpoint 302A may be a middle of an arc length of the curved surface 340.

The axis 318 of the passage 312 may be aligned with the midpoint 320A or may be axially lower than the midpoint 320A. The curved surface 340 may include an axial length 364 that may be separated as a first length 366 and a second length 368, with the first length 366 representing a distance between a top of the axial length 364 and the connection axis 320 and the second length 368 representing a distance between a bottom of the axial length 364 and the connection axis 320. Portions of the curved surface 340 may be referenced using the lengths 366, 368 provided.

In one example, a portion of the curved surface 340 associated with the length 366 may be referred to as a first surface portion 390 and another portion of the curved surface 340 associated with the length 368 may be referred to as a second surface portion 392. A manifold 204A, 204B may be such that second surface portion 392 of the curved surface 340 terminates proximate to an interface (such as the second interface 326B in FIGS. 3A and 3D) between the first manifold module 306 and the second manifold module 304. A manifold 204A, 204B may be such that the second surface portion 392 of the curved surface 340 terminates axially above an opening 310 formed in the second manifold module 304.

The first and second lengths 366, 368 may be equal, the first length 366 may be greater than the second length 368, or the second length 368 may be greater than the first length 366, in different examples. The lengths 364, 366, 368 may be predetermined based on desired or target flow characteristics. For example, the second length 368 may be predetermined based on a relative position to another first connection 314 and/or to an inlet/outlet associated with the manifold 204A, 204B. Additionally, an axial length 364 may be predetermined based on a location of the opening 348 so that the axial length 364 does not overlap the opening 348. The predetermination of the lengths may use a selection from available lengths of available manifold modules, in one example.

The manifold 204A, 204B having the manifold modules 210A, 210B may reduce and/or eliminate space 440 (also in FIG. 4I) for bubble formation within at least the first manifold module 306. The space 440 may be interchangeably referenced as stagnant flow space in the manifold 204A, 204B. For example, without the curved surface 340 that extends into the passage 312, there may have been a space 440 formed by a linear portion of the curved surface 340 but that may have extended fully through the manifold module illustrated by the broken line 340X. The space 440 may permit bubble formation within the passage 312. The bubble formation may be undesirable and may cause problems such as flow instability, slower response time due to pressure changes, channeling, and/or the like. The curved surface 340 may eliminate and/or reduce the space 440 that may be susceptible to bubble formation and fill that space 440 with the curved surface 340 (e.g., with the first surface portion 390 and/or the second surface portion 392 with as little linear portion within the space 440, as possible). As a result, as cooling fluid enters the passage 312, the cooling fluid may be directed against the curved surface 340 and downward into the passage 312, rather than being directed toward corners or other stagnant flow space, such as a space 440, where bubbles may form due to differing flow conditions.

FIG. 3F illustrates a detailed cross-sectional view 300F taken along the area labeled 3F in FIG. 3D. The detailed cross-sectional view 300F illustrates the first connection 314 extending into the opening 310 of a second manifold module 304. The manifold module, the opening 310 or the first connection 314 may be selected based on different operational specifications for the manifold 204A, 204B. For example, the first connection 314 may extend through the coupling outer diameter 356 to engage the second transition 358. The connection axis 320 may be perpendicular to the axis 318 of the passage 312 and may be closer to an upper interface 372 than to a lower interface 374. An axial distance 376 between the connection axis 320 and the upper interface 372 may be less than an axial distance 378 between the connection axis 320 and the lower interface 374. The distances 376, 378 may be predetermined for selection based on flow characteristics, rack spacing constraints, and/or the like.

The interfaces 372, 374 may include the seals 328 arranged within the grooves 380, illustrated as dove-tail grooves, but it should be appreciated that other grooves may be used. The grooves 380 may be formed on a manifold module, such as the manifold modules 302-306, to facilitate coupling and maintenance. For example, each manifold module 302-306 may include the grooves 380 and associated seals 328. In one example, one end of the second manifold module 304 may include the grooves 380 while another end may not, thereby allowing coupling of two manifold modules together. There may be an inner diameter of the grooves, to provide the lip 330. This may support the seal 328 and may allow guidance and centering when coupling the manifold modules together. For example, the lip 330 may fit within a mating feature 382 of an associated manifold module, thereby aligning its passages 394 to provide a passage 312.

FIG. 3G illustrates a side view 300G of a manifold in which the manifold modules 302-306 are shown as transparent to illustrate the seals 328 and the fasteners 324, in accordance with at least one embodiment. The side view 300G may be a reversed location configuration relative to a configuration illustrated in FIG. 3A. A second connection 316 (such as in FIG. 3A) may be associated with the second manifold module 304 and may not be associated with a third manifold module 302 (illustrated at a topmost position relative to FIG. 3A). In line with this configuration, a first manifold module 306 may be at a bottom of a manifold 204A, 204B (relative to FIG. 3A), when arranged vertically in line with the axis 318 of the passage 312, and as a rack stands.

The seals 328 may be arranged at each interface 372, 374 between the second manifold module 304 and the first manifold module 306 or the third manifold modules 302, respectively, and irrespective if they are in a configuration of FIG. 3A or reverse configuration in FIG. 3G. Additionally, the transparency of the components illustrates the extension of the one or more fasteners 324 through each of the manifold modules 302, 304, 306. While a mechanical fastener, in the form of a threaded fastener, is shown, various embodiments may use different types of fasteners in place of, or in combination with, the fasteners 324 shown in FIG. 3G. Various dimensions of any aspect in FIG. 3G may be selected based on desired flow conditions. For example, the lid 308 may include the axial length 364 that may be predetermined for selection so that the seal 328 does not extend beyond the manifold modules. In one instance, the axial length 364 may be predetermined for selection to confine the lid 308 to a second manifold module 304.

A configuration of a lid 308 may be provided herein to also address and overcome flat and/or planar lids (e.g., a lid without a bottom curved portion 430, a lid with a flat or planar inner portion, etc.) by improved liquid flow, reducing stagnant cooling fluid, and reducing space 440 for trapped bubbles. For example, a planar lid may not redirect or otherwise slow flows of cooling fluid when entering the passage 312, which may cause impingement points on opposite sides of the bore. A planar lid may also experience one or more stagnant flow space 440, as flow may contact an opposing wall (illustrated by the broken line 340X in FIG. 3D) of the passage 312 and may collect or otherwise have a reduction in its velocity axially above the contact. The flow problems of the planar lid may lead to damage to a manifold having the planar lid, for example due to erosion-corrosion or bubble formation. The use of curved or otherwise geometric flow path for the lid 308 can eliminate sharp corners that may lead to turbulence and can guide flow along a desired pathway, thereby increasing a likelihood of having fully developed flow while also reducing problems associated with planar surfaces of a planar lid.

FIGS. 4A and 4B illustrate isometric views 400A, 400B of a lid 308, in accordance with at least one embodiment. While the examples may illustrate that the lid 308 may be symmetrical about one or more axes (e.g., an axis 318 extending through the curved surface 340), it should be appreciated that the lid 308 may be asymmetrical in another example. For example, the cutouts 338 may be omitted on one side of the axis to provide a lid 336B that may be asymmetrical, as illustrated by the broken lines in FIG. 4D. The lid 308 may include the curved surface 340, which may extend axially from the top portion 336. In one example, the curved surface 340 may include a radius 414 that may be predetermined for selection based on desired flow characteristics with respect to an incoming flow. For example, the radius 414 may represent a circular, or substantially circular, arc along the curved flow surface.

One or more radius dimension of the radius 414 may be predetermined for selection based on a variety of factors and may be changeable for different manifold modules 302-306. The radius 414 may be a threshold size so that flow is not faster than a threshold amount, because a fast flow of cooling fluid or heated cooling fluid may lead to erosion and, may lead to premature fluid warming for at least cooling fluid that is prior to heat removal. The radius 414 may be approximately one-half of the passage 312 of the manifold 204A, 204B. In another embodiment, the radius 400 may be approximately three-fourths of a diameter of a passage 312 of the manifold 204A, 204B. The radius 400 may be between one-half and three-fourths of the diameter. Different lids may be used for the lid 308 with different curved surfaces 340 based on the aforementioned factors.

In one example, the curved surface 340 may have a rounded or almond shape. That is, a base diameter or a first radial width 402 at a bottom of the curved surface 340 may be less than a body diameter or second radial width 404 at a middle of the curved surface 340 and greater than a tip diameter or third radial width 406 at a tip of the curved surface 340. Also, it is apparent that the second radial width 404 is larger than both the first radial width 402 and the third radial width 406. A rounded shape may facilitate insertion into a passage 312 that has a cylindrical shape, to effectively capture inlet flow while also directing the flow along a desired flow direction. The lid 308 may include a perimeter 408 that is shaped to conform to features of a manifold module 302-306, which may include the cutouts 338. The top portion 336 may have a cross-shape with curved edges at different arms extending from a center location. One or more dimensions may further conform to features of a first manifold module 306, such as a thickness 410 of the top portion 336 being substantially equal to a depth of the opening 332 of the first manifold module 306 so that, upon insertion into the opening 332, a flat surface is formed on the manifold 204A, 204B. Additionally, one or more embodiments may also include an alignment feature so that the lid 308 may not be installed within the opening 332 in an unintended configuration.

FIG. 4C illustrates a side view 400C of a lid 308 having a radius 414 in its curved surface 340, in accordance with at least one embodiment. The radius 414 may be continuous along the curved surface 340 but may include stepped changes or gradual changes to the radius 414. The stepped or gradual changes may include increasing or decreasing radius 414 at different locations along the curved surface 340. The curved surface 340 may extend for a radial length 412 (e.g., radial length, radial width) and for the axial length 364. The radial length 412 may be greater than the axial length 364. In other embodiments, the radial length 412 may be less than or equal to the axial length 364. Further, a length 418 (e.g., radial length, radial width) of the top portion 336, may be larger than the radial length 412. Dimensions herein may be predetermined for selection based on target operating conditions, such as having a longer axial length 364 where a desired flow path is lower along a passage or having a longer radial length 412 when the passage has a larger diameter. Additionally, depending on a location of an inlet flow path, an axial length 364A or 364B may also be adjusted or predetermined for selection to include one or more desired dimensions.

FIG. 4D illustrates a front elevation view 440D of a lid 308 in which the thickness 410 is illustrated along with the axial lengths 364A, 364B, relative to the curved surface 340, in accordance with at least one embodiment. The axial length 364 may be larger than the thickness 410 and, further, the almond shape of the curved surface 340 may be such that a third radial width 406 is less than the second radial width 404. There may be a width 422 of the top portion 336, which may be larger than the largest width of the curved surface 340, in one example. The curved surface 340 in FIG. 4D may be substantially symmetrical with respect to a lid or longitudinal axis 416, but other configurations may not be symmetrical. For example, to direct a flow toward a particular area or to provide more stopping area for the flow, one or more portions may include different radii and/or may have different shapes. In this manner, a variety of different lids (than lid 308) may be predetermined for selection for a particular use case but features such as the thickness 410 and the perimeter 408 may allow use with a common set of manifold assembly components. Similarly, the top portion 336 may also be asymmetrical, for example to provide direction for inserting the top portion 336 into a manifold module 302-306.

FIG. 4E illustrates a side cross-sectional view 400E of a liquid flow simulation within an embodiment of a manifold 204A, 204B in which a lid 308 is positioned to slow and redirect a fluid flow 420 of an inlet, in accordance with at least one embodiment. The second connection 316 (as discussed with reference to FIG. 3A) may be positioned closer to the opening 310A associated with the first connection 314A than to the opening 310C associated with the first connection 314C. The second connection 316 may be incorporated into any of the manifold modules 302-306, and the illustrated configuration is for example purposes only.

As fluid enters the passage 312, it may have a higher velocity due to the cross-sectional area of the respective first connections 314A-314C. As the fluid enters the passage 312, the fluid may slow due to the larger cross-sectional area of the passage 312; and there may be impingement or high-flow contact at an opposite wall of the passage 312 with the respective openings 310A-310C. The manifold modules 302-306 may address and overcome these issues by transferring contact associated with the openings 310A, 310C from the wall of the passage 312 to the respective curved surfaces 340A, 340C. As the fluid contacts the curved surfaces 340A, 340C, the fluid may be redirected along a curved flow path, instead of being driven directly into the opposing wall (illustrated by the broken lines 340X in FIG. 3D) of the passage 312. As the fluid is redirected, the velocity and/or pressure may decrease due to contact with the curved surfaces 340A, 340C. For example, the curved surfaces 340A, 340C may represent a longer flow path than a flow path directly into the opposing wall, which may facilitate decreases in fluid speed and pressure.

Additionally, by preferentially directing the flow along the curved surface 340C, the fluid from the opening 310C may serve as a partial buffer for the fluid entering from the opening 310B, thereby reducing impingement along the wall of the passage 312. The lid 308 may be used with the respective curved surfaces 340A, 340C to reduce pressure and/or velocity of inlet fluids to reduce erosion-corrosion within the passage 312. Moreover, the lids 308 may be used to further reduce risks of erosion-corrosion by incorporating one or more liners or cladding in the passage 312, or portions thereof, with one or more resistant materials, such as nickel.

The lid 308 may be used to reduce a stagnant flow space 440 within the passage 312. For example, without the curved surfaces 340A, 340C directing fluid along the axis 318 of the passage 312, fluid may be slowed at the ends of the manifold (such as in space 440 in FIG. 3D), which may cause bubble formation or otherwise reduce efficiencies by reducing flow of fluid through the manifold assembly. Reduction of the space 440 in which stagnant flow may occur and improve flow through the passage 312.

FIG. 4F is a cross-sectional perspective view 400F of a liquid flow simulation within a manifold incorporating a lid 308 having the curved surface 340A, 340C, in accordance with at least one embodiment. There may be multiple lids 308 having respective curved surfaces 340A, 340C in order to slow fluid velocities and/or decrease pressure of fluid within the passage 312 to reduce impingement that may lead to erosion-corrosion and/or to reduce stagnant flow space, such as a space 440, within the passage 312, among other options.

In this example, higher-pressure flows are illustrated along the curved surfaces 340A, 340C, which may facilitate directing the fluid toward the second connection 316 (as in FIG. 3A) and away from ends of a manifold 204A, 204B. The ability to maintain a fluid pressure in the manifolds 204A, 204B may reduce stagnant flow space, such as a space 440, within the manifolds 204A, 204B, which may improve cooling (either providing cooling fluid or removing heated fluid). For example, as opposed to a configuration in which the lid 308 has a planar surface, the curved surface 340 which effectively decreases an area of a region of the passage 312, thereby maintaining pressures within the region. As a result, the fluid may be driven toward the lower-pressure region associated with the second connection 316 (as discussed in connection with FIG. 3A).

FIG. 4G illustrates a cross-sectional side view 400G of a liquid flow simulation with an embodiment of the manifold incorporating a lid 308 having the curved surface 340, in accordance with at least one embodiment. As discussed herein, there may be one or more lids 308 including respective curved surfaces 340A, 340C in order to slow fluid velocities, reduce turbulence, and provide directed flow within the passage 312 to reduce impingement that may lead to erosion-corrosion and/or to reduce stagnant flow areas within the passage 312. In this example, a fluid flow 420 is directed through the opening 310 and contacts the curved surface 340. As shown by the simulation, normal velocity may remain substantially consistent along the curved surface 340 and toward the second connection 316 (as discussed with reference to FIG. 3A). As a result, the use of the curved surface 340 may reduce instances of erosion-corrosion due to high flow velocities at impingement or transition points.

FIG. 4H illustrates a cross-sectional side view 300H of an embodiment of a flow simulation for a manifold, in accordance with at least one embodiment. The manifold may be any of the manifold 204A, 204B in at least FIG. 3A. The manifold 204A, 204B may incorporate a lid 308 having a planar top portion with the curved surface 340 at a bottom curved portion 430. In FIG. 4H, fluid flow 420 may be directed through the opening 310 and, but for the curved surface 340, would collect within the stagnant flow space, such as a space 440. For example, the stagnant flow space, such as a space 440, may refer to a space where fluid velocity is slowed or stopped, which may cause impingement, choke flow, or other negative flow characteristics. The manifold modules, by incorporating at least the lid 308 herein address and overcome this space 440 in a substantial manner by incorporating the curved surface 340.

FIG. 4I illustrates a cross-sectional side view 400I of a manifold 204A, 204B. This non-limiting example includes a reversed location of the third manifold module 302 forming the passage 312, in the manner of FIG. 3G (relative to the orientation in FIG. 3A). Further illustrated is the lid 308 coupled to a third manifold module 302 (according to the orientation in FIG. 3A). The lid 308 in this example includes the curved surface 340. The curved surface 340 may be positioned within the passage 312 to receive and direct the fluid flow 420 of an inlet away from the stagnant flow space, such as a space 440.

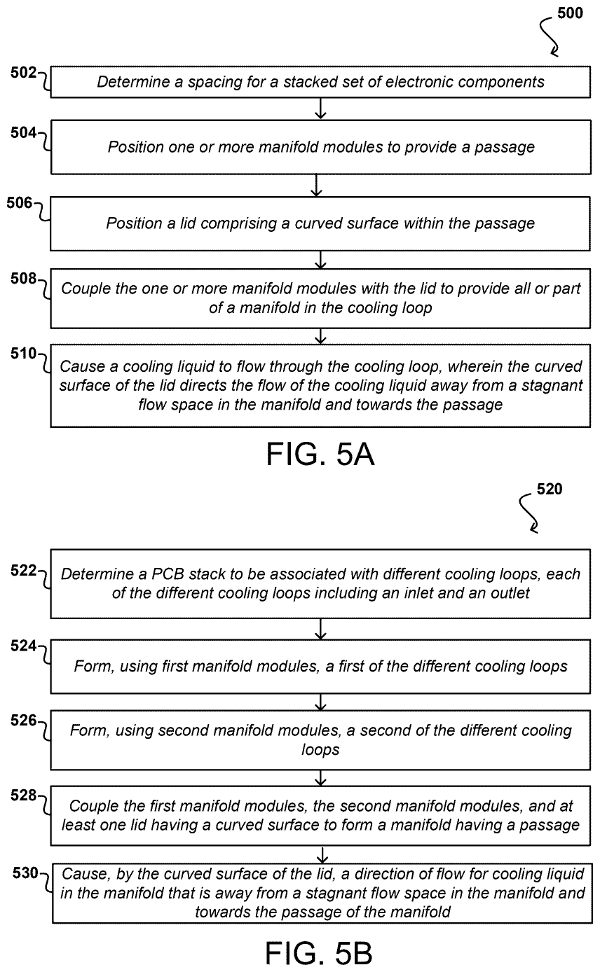

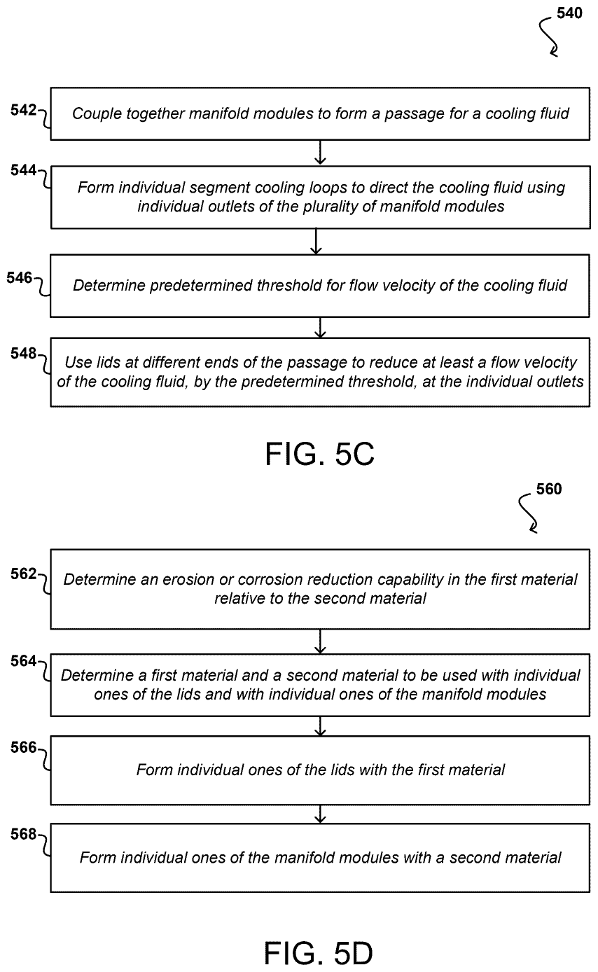

FIG. 5A illustrates an example process or method 500 for using manifold modules and a lid in a manifold of a cooling loop, in accordance with at least one embodiment. The method 500 may include a step to determine 502 a spacing for a stacked set of electronic components. The stacked set of electronic components may be stacked electronic components on different PCBs that are then to be stacked in a server tray or box. The method 500 may include a step to position 504 one or more manifold modules to provide a passage. The method 500 may include a step to position 506 a lid comprising a curved surface within the passage. The step to position 504 the one or more manifold modules may be based in part on the spacing available for the stacked set of electronic components or an application of the stacked set of electronic components. For instance, a shape and size of the one or more manifold modules may be used with the steps 504, 506 based on the spacing to accommodate any remaining room available to provide cooling for the electronic components.

The method 500 may include a step to couple 508 the one or more manifold modules with the lid to provide all or part of a manifold in the cooling loop. For instance, there may be an existing manifold to be adjusted or a new manifold to be provided with the stacked set of electronic components. The one or more manifold modules may be used with an existing manifold module of the existing manifold or a new manifold may be provided with at least the one or more manifold modules and the lid to address one stack of the stacked set of electronic components.

The method 500 may include a step to cause 510 a cooling liquid to flow through the cooling loop. This step may be caused when a workload is being performed using the electronic components. This step may also be caused in a test for leak in the cooling loop. The curved surface of the lid directs the flow of the cooling liquid away from a stagnant flow space in the manifold and towards the passage of the one or more manifold modules.

FIG. 5B illustrates a further example process or method 520 of forming a manifold having a lid for a cooling loop, in accordance with at least one embodiment. The method 520 in FIG. 5B may be used in conjunction or separately from the method 500 in FIG. 5A. For instance, the method 500 in FIG. 5A may provide at least one cooling loop for at least one PCB. The method 520 in FIG. 5B may include a step to determine 522 a PCB stack to be associated with different cooling loops. The PCB stack may include different PCBs with each coupled to one of the different cooling loops that include an inlet and an outlet.

The method 520 may include steps to form 524, using first manifold modules, a first of the different cooling loops and to form 526, using second manifold modules, a second of the different cooling loops. The method 520 may include a step to couple 528 the first manifold modules, the second manifold modules, and at least one lid having a curved surface to form a manifold having a passage. The method 520 may include a step to cause 530, by the curved surface of the lid, a direction of flow for cooling liquid in the manifold that is away from a stagnant flow space in the manifold and towards the passage of the manifold.

The methods in 500 may be used to dissipate heat from one or more electronic components. Each of the methods 500, 520 may include additional, fewer, or alternative operations or steps performed in similar or alternative orders, or at least partially in parallel, within the scope of the various embodiments unless otherwise specifically stated. In this example, a spacing configuration for a stacked set of computing devices is determined 502. For example, the stacked set may include a number of PCBs with respective cold plates that are in a stacked configuration.

The spacing determined in step 502 may also refer to inlet and outlet (e.g., supply and return) spacing to be used with respective cold plates of the respective cooling loops. For example, different unit (server U sizes) densities may lead to different arrangements for the various manifolds. One or more manifold modules may be predetermined for selection for a manifold. The one or more manifold modules may form part of a manifold that may have a variety of different tunable features and/or dimensions. For example, the manifold may include a variety of different supply or return openings, may include openings at different locations, may include a connection at different locations, and/or combinations thereof. In certain embodiments, one or more features may be particularized for a manifold module to facilitate mixing and matching of different configurations. For example, a lid for a manifold module may include seals such that the lid may mate with a variety of different manifold modules.

One or more fasteners may be used to secure the selected one or more manifold modules and at least one lid together. Additionally, in at least one embodiment, certain manifold modules may be secured by other methods, such as welding or brazing. A configuration of the manifold modules may be selected based on the spacing configuration such that one or more flow passages align with one or more mating flow paths of the stacked set. A cooling fluid may then be directed through the manifold and the cold plates in order to dissipate heat from the stacked set of electronic components.

FIG. 5C illustrates an example process or method 540 for using manifold modules in a manifold of a cooling loop, in accordance with at least one embodiment. The method 540 may include a step to couple 542 together manifold modules to form a passage for a cooling fluid. The method 540 may include a step to form 544 individual segment cooling loops to direct the cooling fluid using individual outlets of the plurality of manifold modules. The method 540 may include a step to determine 546 predetermined threshold for flow velocity of the cooling fluid. The method 540 may include a step to use 548 lids at different ends of the passage to reduce at least a flow velocity of the cooling fluid, by the predetermined threshold, at the individual outlets. The lids may be selected from different available lids as part of the step to use 548 different lids. The lids may be formed or manufactured as part of the step to use 548 different lids.

FIG. 5D illustrates a further example process or method 560 of forming a manifold for a cooling loop, in accordance with at least one embodiment. The method 560 may include a step to determine 562 an erosion or corrosion reduction capability in the first material relative to the second material. This step may include use of manufacturer provided ratings for different materials and velocity to be addressed in the manifold. The method 560 may include a step to determine 564 a first material and a second material to be used with individual ones of the lids and with individual ones of the manifold modules. The method 560 may include a step to form 566 individual ones of the lids with the first material. The method 560 may include a step to form 568 individual ones of the manifold modules with a second material.

The methods 540, 560 may include a step or sub-step to determine different shapes or dimensions for the individual ones of the manifold modules, based in part on an application of the plurality of manifold modules. The methods 540, 560 may include a step or sub-step to allow individual ones of the segment cooling loops to include individual ones of the manifold modules with the different shapes or dimensions. The methods 540, 560 may include a step or sub-step to determine one or more operating conditions for the manifold modules based in part on the application. The methods 540, 560 may include a step or sub-step to determine the different shapes or dimensions based in part on the one or more operating conditions. The methods 540, 560 may include a step or sub-step where the one or more operating conditions includes a predetermined flow rate, a predetermined pressure difference, or a predetermined component size. The methods 540, 560 may include a step or sub-step in which the one or more operating conditions are predetermined for an outgoing flow from the manifold or are predetermined for an incoming flow to the manifold.

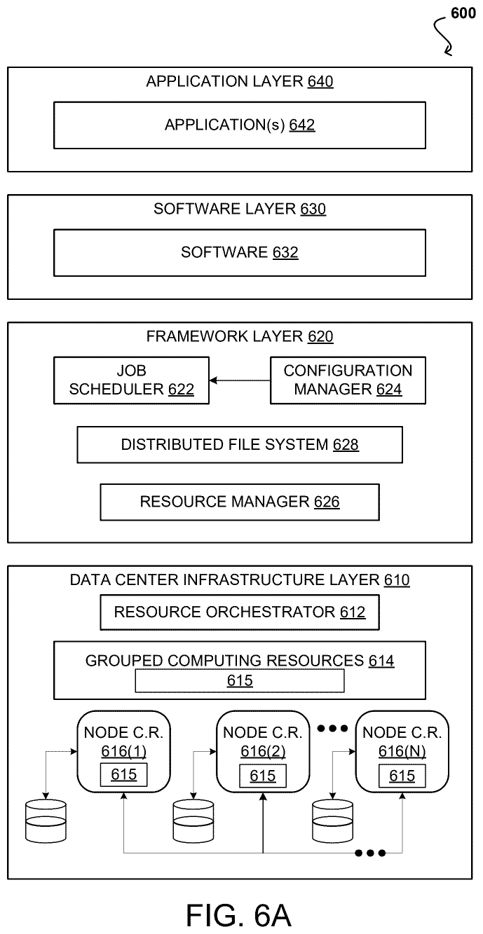

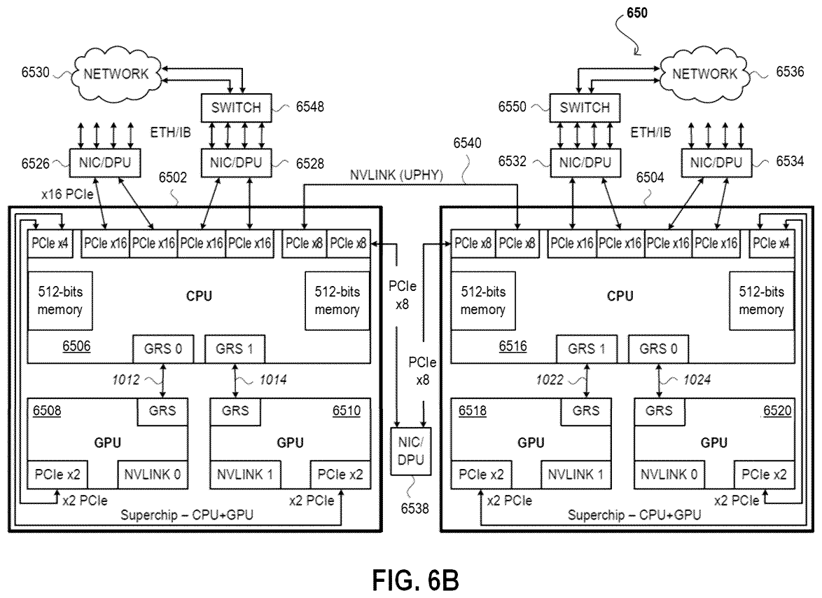

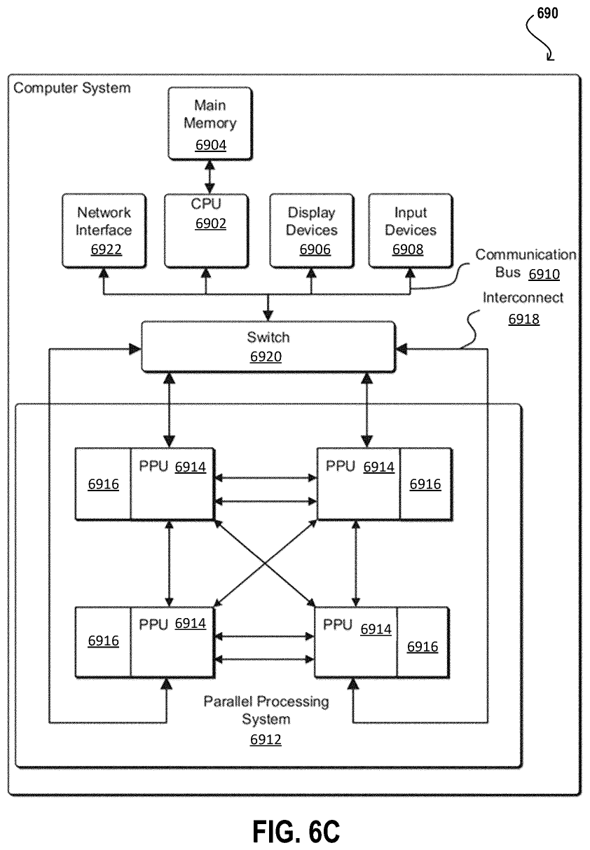

FIG. 6A illustrates an example datacenter 600, in which at least one embodiment may be used. In at least one embodiment, datacenter 600 includes a datacenter infrastructure layer 610, a framework layer 620, a software layer 630, and an application layer 640. FIG. 6A illustrates an example datacenter 600, in which at least one embodiment may be used. In at least one embodiment, datacenter 600 includes a datacenter infrastructure layer 610, a framework layer 620, a software layer 630, and an application layer 640. A datacenter 600 may include one or more racks, such as described in connection with at least FIGS. 1A and 1B. The racks may include one or more server trays. There may be one or more electronic components in the one or more server trays to perform at least part of a workload in the datacenter. The racks and server trays may be represented by at least the datacenter infrastructure layer 610. The electronic components may be presented by the node computing resources 616(1)-616(N) that may be subject to cooling using cold plates.

The datacenter 600 may include a cooling loop to remove heat from the electronic components during performance of the workload. The cooling loop may include a manifold with manifold modules and a lid as detailed in one or more of FIGS. 2A to 5B. The lid may include a curved surface to be positioned within a passage of the manifold. The curved surface may be configured to receive and direct a flow of a cooling fluid away from a stagnant flow space within the manifold. The datacenter 600 may include multiple segment cooling loops to remove heat from the electronic components during performance of the workload. The segment cooling loops may include multiple manifold modules. Individual outlets of the manifold modules can direct a cooling fluid. Multiple lids at different ends of the plurality of manifold modules can reduce a flow velocity of the cooling fluid, by a predetermined threshold, at the individual outlets.

In at least one embodiment, as shown in FIG. 6A, datacenter infrastructure layer 610 may include a resource orchestrator 612, grouped computing resources 614, and node computing resources (“node C.R.s”) 616(1)-616(N), where “N” represents any whole, positive integer. In at least one embodiment, node C.R.s 616(1)-616(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server having one or more of above-mentioned computing resources.

In at least one embodiment, grouped computing resources 614 may include separate groupings of node C.R.s housed within one or more racks (not shown), or many racks housed in datacenters at various geographical locations (also not shown). Separate groupings of node C.R.s within grouped computing resources 614 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for datacenter 600. In at least one embodiment, resource orchestrator may include hardware, software or some combination thereof.

In at least one embodiment, as shown in FIG. 6A, framework layer 620 includes a job scheduler 622, a configuration manager 624, a resource manager 626 and a distributed file system 628. In at least one embodiment, framework layer 620 may include a framework to support software 632 of software layer 630 and/or one or more application(s) 642 of application layer 640. In at least one embodiment, software 632 or application(s) 642 may respectively include web-based service software or applications, such as those provided by Amazon Web Services, Google Cloud and Microsoft Azure. In at least one embodiment, framework layer 620 may be, but is not limited to, a type of free and open-source software web application framework such as Apache Spark™ (hereinafter “Spark”) that may use distributed file system 628 for large-scale data processing (e.g., “big data”). In at least one embodiment, job scheduler 622 may include a Spark driver to facilitate scheduling of workloads supported by various layers of datacenter 600. In at least one embodiment, configuration manager 624 may be capable of configuring different layers such as software layer 630 and framework layer 620 including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resource 614 at datacenter infrastructure layer 610. In at least one embodiment, resource manager 626 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 628 of framework layer 620. The one or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 628 of framework layer 620. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 624, resource manager 626, and resource orchestrator 612 may implement any number and type of self-modifying actions based on any amount and type of data acquired in any technically feasible fashion. In at least one embodiment, self-modifying actions may relieve a datacenter operator of datacenter 600 from making possibly bad configuration decisions and possibly avoiding underused and/or poor performing portions of a datacenter.

In at least one embodiment, datacenter 600 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 600. In at least one embodiment, trained machine learning models corresponding to one or more neural networks may be used to infer or predict information using resources described above with respect to datacenter 600 by using weight parameters calculated through one or more training techniques described herein.

In at least one embodiment, datacenter may use CPUs, application-specific integrated circuits (ASICs), GPUs, FPGAs, a QPU, a PPU, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 615 are used to perform inferencing and/or training operations associated with one or more embodiments. In at least one embodiment, inference and/or training logic 615 may be used in system FIG. 6A for inferencing or predicting operations based, at least in part, on weight parameters calculated using neural network training operations, neural network functions and/or architectures, or neural network use cases described herein.

FIG. 6B is a block diagram that schematically illustrates a computing system that may be a datacenter or a High-Performance Computing (HPC) cluster, in which at least one embodiment from FIGS. 1A-5D may be used. The computing system 650 may include a plurality of subsystems, e.g. multiple processing devices coupled to each other, multiple network devices, and multiple networks, according to at least one embodiment. The computing system 650 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 650 and to one or more external networks 6530, 6536. In the present example, system 650 comprises a packet switch 6548 that connects NIC/DPU 6528 to network 6530, and a packet switch 6550 that connects NIC/DPU 6532 to network 6536.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 650 can include one or more CPUs and one or more GPUs.

FIG. 6B also demonstrates an example architecture of a multi-GPU architecture. As illustrated in the figure, computing system 650 includes a processing device 6502 with a multi-GPU architecture. In particular, processing device 6502 may be a system-on-chip and includes multiple subsystems such as a CPU 6506, a GPU 6508, and a GPU 6510. CPU 6506 can be coupled to GPU 6508 via a die-to-die (D2D) or chip-to-chip (C2C) interconnect 6512, such as a Ground-Referenced Signaling interconnect (GRS interconnect). CPU 6506 can be coupled to GPU 6510 via a D2D or C2C interconnect 6514. CPU 6506 can also couple to GPU 6508 and GPU 6510 via PCIe interconnects.

CPU 6506 can be coupled to one or more NICs or DPUs, which are coupled to one or more networks. For example, as illustrated in FIG. 6B, CPU 6506 is coupled to a first NIC/DPU 6526, which is coupled to a network 6530. CPU 6506 is also coupled to a second NIC/DPU 6528, which is coupled to network 6530 via switch 6548. NIC/DPU 6526 and NIC/DPU 6528 can be coupled to network 6530 over Ethernet (ETH), NVLINK or InfiniBand (IB) connections, for example.

Computing system 650 also includes a processing device 6504 with a multi-GPU architecture. In particular, processing device 6504 includes multiple subsystems including a CPU 6516, a GPU 6518, and a GPU 6520. CPU 6516 can be coupled to GPU 6518 via an D2D or C2C interconnect 6522. CPU 6516 can be coupled to GPU 6520 via a D2D or C2C interconnect 6524. CPU 6516 can also couple to GPU 6518 and GPU 6520 via PCIe interconnects. CPU 6516 can be coupled to one or more NICs or DPUs, which are coupled to one or more networks. For example, as illustrated in FIG. 6B, CPU 6516 is coupled to a first NIC/DPU 6532, which is coupled to a network 6536. CPU 6516 is also coupled to a second NIC/DPU 6534, which is coupled to network 6536 via switch 6550. NIC/DPU 6532 and NIC/DPU 6534 can be coupled to network 6536 over Ethernet (ETH), NVLINK or InfiniBand (IB) connections.

In at least one embodiment, processing device 6502 and processing device 6504 can communication with each other via a NIC/DPU 6538, such as over PCIe interconnects. Processing device 6502 and processing device 6504 can also communicate with each other over a high-bandwidth communication interconnects 6540, such as an NVLink interconnect or other high-speed interconnects. The packet switches in FIG. 6B may comprise, for example, Nvidia Quantum-2 switches. The NICs/DPUs in the figure may comprise, for example, Nvidia Bluefield DPUs.

In various embodiments, any of the network devices of the computing system 650, e.g., any of NICs/DPUs 6526, 6528, 6532, 6534 and 6538, and/or any of switches 6548 and 6550, may include a shaped leak sensor that can match a geometry around components and features in the computing system 650 and that can be communicatively coupled together to extend leak detection capabilities.

FIG. 6C illustrates a computer system, according to at least one example, in which at least one embodiment from FIGS. 1A-5D may be used. In at least one embodiment, computer system 690 is configured to implement various processes and methods described throughout this disclosure.

In at least one embodiment, computer system 690 comprises, without limitation, at least one central processing unit (“CPU”) 6902 that is connected to a communication bus 6910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 690 includes, without limitation, a main memory 6904 and control logic (e.g., implemented as hardware, software, or a combination thereof) and data are stored in main memory 6904 which may take form of random access memory (“RAM”). In at least one embodiment, a network interface subsystem (“network interface”) 6922 provides an interface to other computing devices and networks for receiving data from and transmitting data to other systems from computer system 690.

In at least one embodiment, computer system 690, in at least one embodiment, includes, without limitation, input devices 6908, parallel processing system 6912, and display devices 6906 which can be implemented using a conventional cathode ray tube (“CRT”), liquid crystal display (“LCD”), light emitting diode (“LED”), plasma display, or other suitable display technologies. In at least one embodiment, user input is received from input devices 6908 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 6904 and/or secondary storage. Computer programs, if executed by one or more processors, enable system 690 to perform various functions in accordance with at least one embodiment. memory 6904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 6902; parallel processing system 6912; an integrated circuit capable of at least a portion of capabilities of both CPU 6902; parallel processing system 6912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 690 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 6912 includes, without limitation, a plurality of parallel processing units (“PPUs”) 6914 and associated memories 6916. In at least one embodiment, PPUs 6914 are connected to a host processor or other peripheral devices via an interconnect 6918 and a switch 6920 or multiplexer. In at least one embodiment, parallel processing system 6912 distributes computational tasks across PPUs 6914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 6914, although such shared memory may incur performance penalties relative to use of local memory and registers resident to a PPU 6914. In at least one embodiment, operation of PPUs 6914 is synchronized through use of a command such as_syncthreads(), wherein all threads in a block (e.g., executed across multiple PPUs 6914) to reach a certain point of execution of code before proceeding.

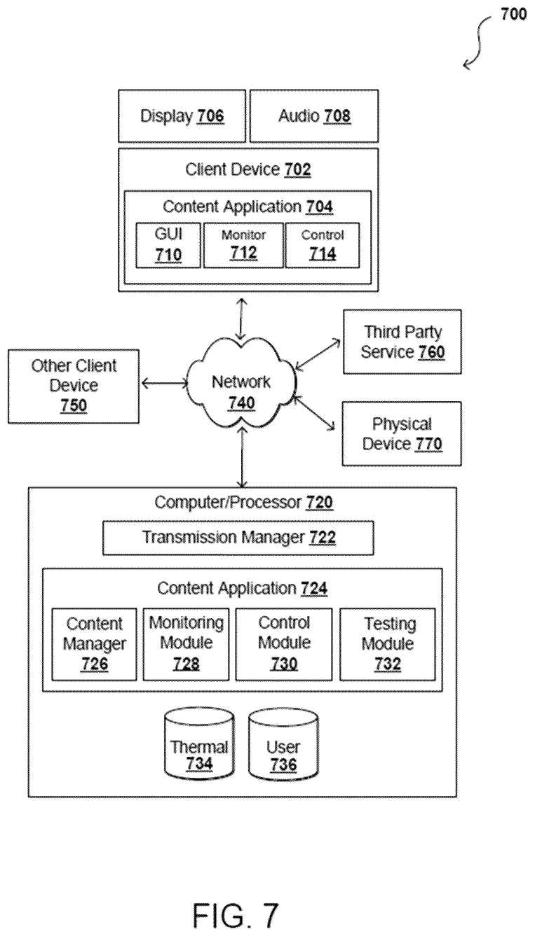

FIG. 7 illustrates an example network configuration 700 of components that can be used to implement aspects of various embodiments, such as to provide, generate, modify, encode, process, fuse, and/or transmit generated image data, calculated measurements, or other such content. In at least one embodiment, a client device 702 can generate or receive data for a session using components of a content application 704 on the client device 702 and data stored locally on that client device. In at least one embodiment, a content application 724 executing on a computer or processor 720 (e.g., a cloud server or control system) may initiate a session associated with at least one client device 702 (e.g., a vehicle or robot), as may use a session manager and user data stored in a user database 736, and can cause content such as liquid coolant or server thermal data to be selected and/or retrieved from a repository 734 to be used by a testing module 732 to calculate one or more performance metrics for a monitoring module 728, which can provide flow data or thermal data to a control module 730 to control a flow or temperature, in an environment where the data is to be used to determine appropriate operation.

A content manager 726 may work with at these various modules to perform testing and analysis, and potentially instruct any actions to be taken in response to a performance metric failing to satisfy an operational requirements. At least a portion of this data or instructional content can be transmitted to the client device 702 and/or a physical device 770 using an appropriate transmission manager 722 to send by download, streaming, or another such transmission channel. An encoder may be used to encode and/or compress at least some of this data before transmitting to the client device 702. In at least one embodiment, the client device 702 receiving such content can provide this content to a corresponding content application 704, which may also or alternatively include a graphical user interface 710, a flow monitor module 712, and a control module 714 for use in providing, synthesizing, rendering, compositing, modifying, or using content for presentation, navigation, control, (or other purposes) on or by the client device 702, such as may be transmitted to the physical device 770. In some embodiments, the computer/processor 720 and client device 702 may be able to communicate directly without needing to transmit data over a network 740, in order to avoid issues with latency and availability, etc. A decoder may also be used to decode data received over the network 740 for presentation via client device 702, such as imaging content or performance metrics through a display device 706 and audio, such as corresponding sounds or synthesized speech, through at least one audio playback device 708, such as speakers or headphones. In at least one embodiment, at least some of this content may already be stored on, rendered on, or accessible to client device 702 such that transmission over a network 740 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 720, or user database 736, to the client device 702. In at least one embodiment, at least a portion of this content can be obtained, enhanced, and/or streamed from another source, such as a third party service 760 or other client device 750, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least one embodiment, a cold plate herein may include adjustable fins forming microchannels for fluid to flow through. In at least one embodiment, fins in a cold plate allow transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a datacenter or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a datacenter or at least partially using cloud computing resources.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. Term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset,” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, term “plurality” indicates a state of being plural (e.g., “a plurality of items” indicates multiple items). A plurality is at least two items, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors-for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways such as by receiving data as a parameter of a function call or a call to an application programming interface. In some implementations, process of obtaining, acquiring, receiving, or inputting analog or digital data can be accomplished by transferring data via a serial or parallel interface. In another implementation, process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data can be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A cooling system, comprising:
a plurality of manifold modules to be stacked together to provide a manifold in the cooling system; and
a plurality of lids to enclose the plurality of manifold modules, wherein the plurality of manifold modules and the plurality of lids allow the cooling system to comprise different segment cooling loops comprising different manifold sizes or different manifold properties.

2. The cooling system of claim 1, wherein the different manifold sizes comprise different shapes or dimensions that are internal or external for the plurality of manifold modules, and wherein the different manifold properties comprise a predetermined flow rate, a predetermined pressure difference, or a predetermined component size.

3. The cooling system of claim 1, further comprising:
stacked printed circuit boards (PCBs), wherein the individual segment cooling loops are associated with individual PCBs of the stacked PCBs.

4. The cooling system of claim 1, wherein individual ones of the plurality of lids comprise a first material and individual ones of the plurality of manifold modules comprise a second material, as part of the different manifold properties, wherein the first material is used based in part on an erosion or corrosion reduction for the individual ones of the plurality of lids, relative to the second material.

5. The cooling system of claim 1, further comprising:
one or more source connections in the plurality of manifold modules, the one or more source connections to fluidly couple the manifold or individual ones of the plurality of manifold modules to an external cooling loop of the cooling system.

6. A plurality of segment cooling loops comprising a plurality of manifold modules, individual outlets of the plurality of manifold modules to direct a cooling fluid, and a plurality of lids at different ends of the plurality of manifold modules to reduce a flow velocity of the cooling fluid, by a predetermined threshold, at the individual outlets.

7. A manifold for a cooling loop, comprising:
a plurality of manifold modules to couple together to form a passage for a cooling fluid;
individual outlets of the plurality of manifold modules to form individual segment cooling loops to direct the cooling fluid from the manifold; and
a plurality of lids at different ends of the passage to reduce a flow velocity of the cooling fluid, by a predetermined threshold, at the individual outlets.

8. The manifold of claim 7, further comprising:
one or more seals arranged at interfaces between individual ones of the plurality of manifold modules, individual ones of the one or more seals positioned to allow individual ones of the different segment cooling loops to be stacked vertically together within a server tray or a rack.

9. The manifold of claim 7, further comprising:
one or more lips between individual ones of the plurality of manifold modules; and
one or more recesses between the individual ones of the plurality of manifold modules to receive the one or more lips, the one or more lips and the one or more recesses to support the passage formed within the plurality of manifold modules.

10. The manifold of claim 7, wherein individual ones of the plurality of lids comprise a first material and individual ones of the plurality of manifold modules comprise a second material, wherein the first material is used based in part on an erosion or corrosion reduction for the individual ones of the plurality of lids, relative to the second material.

11. The manifold of claim 7, wherein the individual segment cooling loops comprise individual ones of the plurality of manifold modules, and wherein the individual ones of the plurality of manifold modules comprise different shapes or dimensions.

12. The manifold of claim 11, wherein the different shapes or dimensions is predetermined based in part on one or more operating conditions for the manifold or the plurality of manifold modules.

13. The manifold of claim 12, wherein the one or more operating conditions comprise a predetermined flow rate, a predetermined pressure difference, a predetermined component size, or a predetermined spacing associated with stacked printed circuit boards (PCBs) to be coupled to the individual segment cooling loops.

14. The manifold of claim 12, wherein the one or more operating conditions are predetermined for an outgoing flow from the manifold or are predetermined for an incoming flow to the manifold.

15. The manifold of claim 7, further comprising:
one or more source connections in the plurality of manifold modules, the one or more source connections to fluidly couple the manifold or individual ones of the plurality of manifold modules to an external cooling loop, relative to the individual segment cooling loops.

16. A datacenter comprising:
one or more racks comprising one or more server trays;
one or more electronic components in the one or more server trays to perform at least part of a workload in the datacenter; and
a plurality of segment cooling loops to remove heat from the electronic components during performance of the workload, the plurality of segment cooling loops comprising a plurality of manifold modules, individual outlets of the plurality of manifold modules to direct a cooling fluid, and a plurality of lids at different ends of the plurality of manifold modules to reduce a flow velocity of the cooling fluid, by a predetermined threshold, at the individual outlets.

17. A method for a cooling loop, comprising:
coupling together a plurality of manifold modules to form a passage for a cooling fluid;
forming individual segment cooling loops to direct the cooling fluid using individual outlets of the plurality of manifold modules; and
using a plurality of lids at different ends of the passage to reduce at least a flow velocity of the cooling fluid, by a predetermined threshold, at the individual outlets.

18. The method of claim 17, further comprising:
positioning one or more seals at interfaces between individual ones of the plurality of manifold modules to allow the individual segment cooling loops to be stacked vertically within a server tray or a rack.

19. The method of claim 17, further comprising:
receiving one or more lips, between individual ones of the plurality of manifold modules, into one or more recesses between the individual ones of the plurality of manifold modules, the one or more lips and the one or more recesses to support the passage formed within the plurality of manifold modules.

20. The method of claim 17, further comprising:
determining a first material and a second material to be used with individual ones of the plurality of lids and with individual ones of the plurality of manifold modules, based in part on an erosion or corrosion reduction capability in the first material relative to the second material;
forming individual ones of the plurality of lids with the first material; and
forming individual ones of the plurality of manifold modules with a second material.

21. The method of claim 17, further comprising:
determining different shapes or dimensions for individual ones of the plurality of manifold modules, based in part on an application of the plurality of manifold modules; and
allowing the individual segment cooling loops to comprise individual ones of the plurality of manifold modules with the different shapes or dimensions.

22. The method of claim 21, further comprising:
determining one or more operating conditions for the plurality of manifold modules based in part on the application; and
determining the different shapes or dimensions based in part on the one or more operating conditions.

23. The method of claim 22, wherein the one or more operating conditions comprise a predetermined flow rate, a predetermined pressure difference, or a predetermined component size.

24. The method of claim 22, wherein the one or more operating conditions are predetermined for an outgoing flow from the manifold or are predetermined for an incoming flow to the manifold.

25. The method of claim 17, further comprising:
fluidly coupling individual ones of the plurality of manifold modules to an external cooling loop, relative to the individual segment cooling loops, using one or more source connections in the plurality of manifold modules.

26. The method of claim 17, further comprising:
determining one or more target locations of a server tray or box for one or more of the segment cooling loops; and
allowing one or more manifolds that may be configured for assembly and modularity to fit the one or more target locations based in part on the plurality of manifold modules being coupled together to provide the one or more manifolds.
